(19) United States
(12) Patent Application Publication
(10) Pub. No.: US 2024/0224648 A1
(43) Pub. Date: Jul. 4, 2024

(54) DISPLAY PANEL

(71) Applicant: Samsung Display Co., Ltd., Yongin-si (KR)

(72) Inventors: JEONGYOON LEE, Yongin-si (KR); KYUNGHO KIM, Yongin-si (KR); OK-KYUNG PARK, Yongin-si (KR)

(73) Assignee: Samsung Display Co., Ltd., Yongin-si (KR)

(21) Appl. No.: 18/395,845

(22) Filed: Dec. 26, 2023

(30) Foreign Application Priority Data
Dec. 28, 2022 (KR) 10-2022-0186932

(51) Int. Cl. H10K 59/131

(52) U.S. Cl. CPC H10K 59/131

(57) ABSTRACT

A display panel includes a base layer bendable with respect to a virtual axis, a driving element layer including a transistor, and a light emitting element layer including a first electrode, emission layers disposed on the first electrode, and second electrodes disposed on the emission layers. One of the second electrodes is electrically connected to the transistor. The first electrode includes first sub electrodes overlapping the emission layers and a connection pattern layer that electrically connects the first sub electrodes. The connection pattern layer includes a first connection pattern layer that electrically connects the first sub electrodes in a first direction parallel to the virtual axis, and a second connection pattern layer that electrically connects the first sub electrodes in a second direction intersecting the first direction. The first connection pattern layer has a density greater than that of the second connection pattern layer.

### CROSS-REFERENCE TO RELATED APPLICATION(S)

This application claims priority to and benefits of Korean Patent Application No. 10-2022-0186932 under 35 U.S.C. § 119, filed on Dec. 28, 2022, the entire contents of which are incorporated herein by reference.

### BACKGROUND

### 1. Technical Field

Embodiments relate to a display panel having improved display quality.

### 2. Description of the Related Art

Multimedia electronic apparatuses such as televisions, mobile phones, tablet computers, navigators, game consoles, and the like includes a display panel for displaying an image.

The display panel includes a light emitting element and a pixel driver for driving the light emitting element. To improve reliability of the display panel, research on connection between the light emitting element and the pixel driver has been conducted.

### SUMMARY

Embodiments provide a display panel capable of preventing or minimizing afterimage defects, capable of increasing a lifespan, and capable of improving electrical reliability.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display panel may include: a base layer bendable with respect to a virtual axis; a driving element layer including a transistor; and a light emitting element layer including a first electrode, a plurality of emission layers disposed on the first electrode, and a plurality of second electrodes disposed on the emission layers, wherein at least one of the second electrodes may be electrically connected to the transistor, the first electrode may include a plurality of first sub electrodes overlapping the plurality of emission layers and a connection pattern layer that electrically connects the first sub electrodes to each other, the connection pattern layer may include: a first connection pattern layer that electrically connects the plurality of first sub electrodes to each other in a first direction parallel to the virtual axis; and a second connection pattern layer that electrically connects the plurality of first sub electrodes to each other in a second direction intersecting the first direction, and a density of the first connection pattern layer may be greater than a density of the second connection pattern layer.

In an embodiment, a folding area that is folded with respect to the virtual axis and a non-folding area that is not folded with respect to the virtual axis may be defined in the display panel.

In an embodiment, a density of the second connection pattern layer overlapping the folding area may be less than a density of the second connection pattern layer overlapping the non-folding area.

In an embodiment, the density of the second connection pattern layer overlapping the folding area may gradually decrease as being closer to the virtual axis.

In an embodiment, the first connection pattern layer may include a plurality of first connection parts that electrically connect the plurality of first sub electrodes, which are adjacent to each other in the first direction, to each other, and the second connection pattern layer may include a plurality of second connection parts that electrically connect the plurality of first sub electrodes, which are adjacent to each other in the second direction, to each other.

In an embodiment, a first distance between two second connection parts, which are adjacent to each other in the folding area, of the second connection parts in the first direction may be different from a second distance between two second connection parts, which are adjacent to each other in the non-folding area, of the second connection parts in the first direction.

In an embodiment, the first distance in the folding area may be greater than the second distance in the non-folding area.

In an embodiment, a number of the plurality of second connection parts in the folding area in a same surface size and a number of the plurality of second connection parts in the non-folding area in the same surface size may be different from each other.

In an embodiment, the number of the plurality of second connection parts disposed in the first direction may gradually decrease as being closer to the virtual axis.

In an embodiment, the plurality of second connection parts may include: a plurality of first sub connection parts having a multilayer structure; and a plurality of second sub connection parts having a single-layer structure.

In an embodiment, each of the plurality of first sub connection parts may include: a first conductive layer; a metal layer disposed on the first conductive layer; and a second conductive layer disposed on the metal layer, and each of the plurality of second sub connection parts may include the metal layer.

In an embodiment, the plurality of first sub connection parts may be disposed in the non-folding area, and the plurality of second sub connection parts may be disposed in the folding area.

In an embodiment, a number of the plurality of second sub connection parts disposed in the first direction may gradually increase as being closer to the virtual axis.

In an embodiment, the display panel may further include: a voltage line that receives a power voltage; and a plurality of connection lines that connect the voltage line to the first electrode, wherein the voltage line and the plurality of connection lines may be disposed outside the first electrode.

In an embodiment, a density of the plurality of connection lines disposed in the folding area may be greater than a density of the plurality of connection lines disposed in the non-folding area.

In an embodiment, the the light emitting element layer may further include: a pixel defining layer including a pixel opening, through which a portion of the first electrode is exposed, the pixel defining layer disposed on the first electrode; and a separator disposed on the pixel defining layer, wherein each of the plurality of emission layers may overlap the pixel opening.

In an embodiment, the connection pattern layer may overlap the separator in a plan view.

In an embodiment, the display panel may further include a connection line that electrically connects the transistor to the at least one of the plurality of second electrodes, the connection line including: a first connection portion connected to the at least one of the plurality of second electrodes; a second connection portion connected to the transistor; and an extension part extending from the first connection portion and electrically connecting the first connection portion to the second connection portion.

In an embodiment, the connection pattern layer may not overlap the first connection portion in a plan view.

In an embodiment, a display panel including a folding area that is folded with respect to a virtual axis and a non-folding area that is not folded with respect to the virtual axis, may include: a driving element layer including a transistor; and a light emitting element layer including a first electrode, a plurality of emission layers disposed on the first electrode, and a plurality of second electrodes disposed on the emission layers, wherein at least one of the plurality of second electrodes is electrically connected to the transistor, the first electrode may include a plurality of first sub electrodes overlapping the plurality of emission layers and a connection pattern layer that electrically connects the plurality of first sub electrodes to each other, and a density of the connection pattern layer in the folding area and a density of the connection pattern layer in the non-folding area are different from each other.

In an embodiment, the density of the connection pattern layer in the folding area may gradually decrease as being closer to the virtual axis.

In an embodiment, the connection pattern layer may include: a plurality of first connection parts that electrically connect the first sub electrodes, which are adjacent to each other in a first direction parallel to the virtual axis, to each other; and a plurality of second connection parts that electrically connect the first sub electrodes, which are adjacent to each other in a second direction intersecting the first direction, to each other.

In an embodiment, a first distance between two second connection parts, which are adjacent to each other in the folding area, of the second connection parts in the first direction may be different from a second distance between two second connection parts, which are adjacent to each other in the non-folding area, of the second connection parts in the first direction.

In an embodiment, the first distance in the folding area may be greater than the second distance in the non-folding area.

In an embodiment, a number of the plurality of second connection parts in the folding area and a number of the plurality of second connection parts in the non-folding area may be different from each other.

In an embodiment, the number of the plurality of second connection parts disposed in the first direction may gradually decrease as being closer to the virtual axis.

In an embodiment, a display panel including a folding area that is folded and a non-folding area that is not folded with respect to a virtual axis, may include: a driving element layer including a transistor; and a light emitting element layer including a first electrode, a plurality of emission layers disposed on the first electrode, and a plurality of second electrodes disposed on the emission layers, wherein each of the plurality of second electrodes is electrically connected to the transistor, the first electrode include a plurality of first sub electrodes overlapping the plurality of emission layers and a connection pattern layer that electrically connects the first sub electrodes to each other, the connection pattern layer may include: a plurality of first sub connection parts having a multilayer structure; and a plurality of second sub connection parts having a single-layer structure, the plurality of first sub connection parts may be disposed in the non-folding area, and the plurality of second sub connection parts may be disposed in the folding area.

In an embodiment, each of the plurality of first sub connection parts may include: a first conductive layer; a metal layer disposed on the first conductive layer; and a second conductive layer disposed on the metal layer, and each of the plurality of second sub connection parts may include the metal layer.

In an embodiment, a number of the plurality of second sub connection parts disposed in a direction parallel to the virtual axis may gradually increase as being closer to the virtual axis.

### BRIEF DESCRIPTION OF THE DRAWINGS

The accompanying drawings are included to provide a further understanding of the invention, and are incorporated in and constitute a part of the description. The drawings illustrate embodiments and, together with the description, serve to explain principles of the invention. In the drawings:

FIG. 1 is a schematic perspective view of a display device according to an embodiment;

FIG. 2A is a schematic view illustrating a state in which the display device of FIG. 1 is in-folded along a first folding axis;

FIG. 2B is a schematic view illustrating a state in which the display device of FIG. 1 is out-folded along the first folding axis;

FIG. 3A is a schematic view illustrating a state in which the display device of FIG. 1 is in-folded along a second folding axis;

FIG. 3B is a schematic view illustrating a state in which the display device of FIG. 1 is out-folded along the second folding axis;

FIG. 4 is an exploded schematic perspective view of the display device according to an embodiment;

FIG. 5 is a block diagram of the display device according to an embodiment;

FIG. 6A is a schematic diagram of an equivalent circuit of a pixel according to an embodiment;

FIG. 6B is a schematic diagram of an equivalent circuit of a pixel according to an embodiment;

FIG. 7A is a schematic plan view of a display panel according to an embodiment;

FIG. 7B is a schematic plan view of a display panel according to an embodiment;

FIG. 8A is an enlarged schematic plan view illustrating a partial area of the display panel according to an embodiment;

FIG. 8B is an enlarged schematic plan view illustrating a partial area of the display panel according to an embodiment;

FIG. 9 is a schematic cross-sectional view of the display panel according to an embodiment;

FIG. 10A is an enlarged schematic view illustrating an area AA of FIG. 9;

FIG. 10B is an enlarged schematic view illustrating an area BB of FIG. 9;

FIG. 11 is a schematic cross-sectional view of the display panel according to an embodiment;

FIG. 12 is a schematic plan view of a display panel according to an embodiment;

FIG. 13A is an enlarged schematic view illustrating an area CC of FIG. 12;

FIG. 13B is an enlarged schematic view illustrating an area DD′ of FIG. 12;

FIG. 13C is an enlarged schematic view illustrating an area EE of FIG. 12;

FIG. 14 is a schematic plan view of a display panel according to an embodiment;

FIG. 15A is a schematic cross-sectional view taken along line II-II′ of FIG. 14;

FIG. 15B is a schematic cross-sectional view taken along line III-III′ of FIG. 14; and

FIG. 16 is a schematic cross-sectional view of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

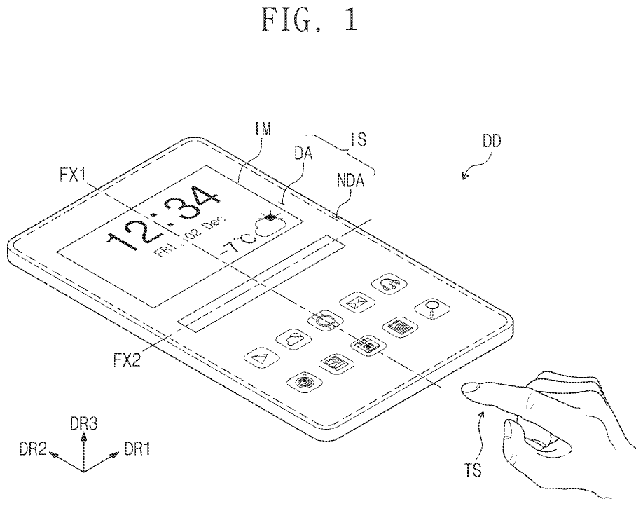

FIG. 1 is a schematic perspective view of a display device according to an embodiment.

Referring to FIG. 1, a display device DD may have a rectangular shape having short sides parallel to a first direction DR1 and lone sides parallel to a second direction DR2 intersecting the first direction DR1. However, the shape of the display device DD is not limited thereto. For example, the display device DD may have various shapes. For example, the display device DD may have a rectangular shape having long sides parallel to the first direction DR1 and short sides parallel to the second direction DR2 or may have a square shape having a side parallel to the first direction DR1 and a side parallel to the second direction DR2, which have the same length.

The display device DD may be a foldable electronic device. For example, the display device DD according to an embodiment may be folded with respect to a folding axis FX1 or FX2 extending in a certain direction. The folding axis FX1 or FX2 may be a virtual axis. For example, the folding axis FX1 or FX2 may correspond to an axis that does not exist. Hereinafter, the folded state with respect to the folding axis FX1 or FX2 may be defined as a folded state, and the unfolded state is defined as a non-folded state. The folding axis FX1 or FX2 may be a rotation axis that is a virtual line occurring in case that the display device DD is folded. For example, the folding axis FX1 or FX2 may be defined by an instrument structure provided in the display device DD.

The folding axis FX1 or FX2 may extend in the first direction DR1 or the second direction DR2. In an embodiment, the folding axis extending in the second direction DR2 may be defined as a first folding axis FX1, and a folding axis extending in the first direction DR1 may be defined as a second folding axis FX2. The display device DD may be folded with respect to at least one folding axis of the first and second folding axes FX1 and FX2.

The display device DD according to an embodiment may be used for large-sized display devices such as televisions, monitors, and the like and small and middle-sized display devices such as mobile phones, tablet PC, navigation units for vehicles, game consoles, and the like. However, this is an example, the display device DD may be adopted for other electronic devices unless departing from the spirit and scope of the invention.

As illustrated in FIG. 1, the display device DD may display an image IM in a third direction DR3 on a display surface IS that is parallel to each of the first and second directions DR1 and DR2. The display surface IS on which the image IM is displayed may correspond to a front surface of the display device DD.

The display surface IS of the display device DD may be divided into a plurality of areas. A display area DA and a non-display area NDA may be defined on the display surface IS of the display device DD. The display area DA may be an area on which an image IM is displayed, and a user may see the image IM through the display area DA. The display area DA may have a rectangular shape. The non-display area NDA may surround the display area DA. Thus, the shape of the display area DA may be substantially defined by the non-display area NDA. However, this is an example. For example, the non-display area NDA may be disposed adjacent to only one side of the display area DA or be omitted. The display device DD according to an embodiment may be implemented according to various embodiments, but embodiments are not limited thereto.

The non-display area NDA may be an area which is adjacent to the display area DA and on which the image IM is not displayed. A bezel area of the display device DD may be defined by the non-display area NDA.

The display device DD according to an embodiment may sense a user's input TS applied from the outside. The user's input TS may include various types of external inputs such as a portion of user's body, light, heat, a pressure, or the like. In an embodiment, the user's input TS is illustrated as a user's hand applied to the front surface. However, this is an example. For example, as described above, the user's input TS may be provided in various shapes. The display device DD may sense the user's input TS applied to a side surface or the rear surface of the display device DD according to a structure of the display device DD, but embodiments are not limited thereto.

The display device DD may activate the display surface IS to display the image IM and also sense the user's input TS. In an embodiment, an area on which the user's input TS is sensed may be provided on the display area DA on which the image IM is displayed. However, this is an example. For example, the area on which the user's input TS may be provided on the non-display area NDA or provided on an entire area of the display surface IS.

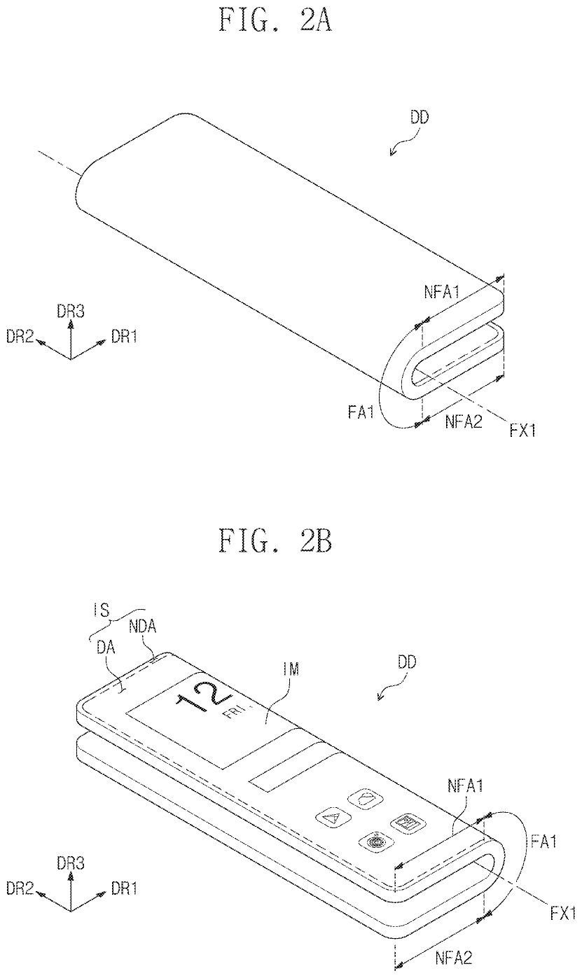

FIG. 2A is a schematic view illustrating a state in which the display device of FIG. 1 is in-folded along the first folding axis. FIG. 2B is a schematic view illustrating a state in which the display device of FIG. 1 is out-folded along the first folding axis.

Referring to FIGS. 1 to 2A, the display device DD may be a foldable display device DD. The display device DD may be folded based on the folding axis extending in a certain direction (e.g., the first folding axis FX1 or the second folding axis FX2). FIG. 2A illustrates the display device DD folded based on the first folding axis FX1 extending to the second direction DR2.

A plurality of areas may be defined in the display device DD according to an operation type. The plurality of areas may be divided into the first folding area FA1 and at least one non-folding area NFA1 or NFA2. The first folding area FA1 may be defined between two non-folding areas NFA1 and NFA2.

The first folding area FA1 may be an area that is folded with respect to the first folding axis FX1 to substantially define a curvature. For example, the first folding axis FX1 may extend in the second direction DR2, e.g., in a long axis direction of the display device DD. The first folding area FA1 may be defined as an area that is folded along the first folding axis FX1 and extends in the second direction DR2.

In an embodiment, the non-folding areas NFA1 and NFA2 may include a first non-folding area NFA1 and a second non-folding area NFA2. The first non-folding area NFA1 may be adjacent to a side of the first folding area FA1 in the first direction DR1, and the second non-folding area NFA2 may be adjacent to another side of the first folding area FA1 in the first direction DR1. Each of the first non-folding area NFA1 and the second non-folding area NFA2 may be an area that does not have a curvature without being substantially folded.

The display device DD may be in-folded or out-folded. The in-folding refers to folding of the display surface IS to face each other, and the out-folding refers to folding of the rear surface of the display device DD to face each other. For example, the folding of the display surfaces of the different non-folding areas NFA1 and NFA2 to face each other may be defined as in-folding, and the folding of the display surfaces of the different non-folding areas NFA1 and NFA2 to face the outside may be defined as out-folding.

The display device DD illustrated in FIG. 2A may be in-folded so that the display surface IS of the first non-folding area NFA1 and the display surface IS of the second non-folding area NFA2 may face each other. As the first non-folding area NFA1 rotates in a clockwise direction along the first folding axis FX1, the display device DD may be in-folded. To in-fold the display device DD so that the first non-folding area NFA1 and the second non-folding area NFA2 may be aligned, the first folding axis FX may be defined at a center portion of the display device DD in the first direction DR1.

Referring to FIG. 2B, the display device DD may be out-folded with respect to the first folding axis FX1. The display device DD may display the image IM in case that a display surface IS of the first non-folding area NFA1 and a display surface IS of the second non-folding area NFA2 are exposed to the outside. For example, the display surface of the first folding area FA1 exposed to the outside may also display the image IM. Referring to FIG. 1, the display device DD may display the image IM in an unfolded state. The first non-folding area NFA1, the second non-folding area NFA2 and the first folding area FA1 may respectively display images providing pieces of information, which are independent of each other, or respectively display portions of an image providing a piece of information.

The display device DD may be manufactured to have both the in-folding state and the out-folding state or may be manufactured to have one of the in-folding state and the out-folding state.

In FIGS. 2A and 2B, the first folding area FA1 (as a single first folding area) may be defined in the display device DD, but embodiments are not limited thereto. For example, a plurality of folding areas may be defined in the display device DD according to an embodiment.

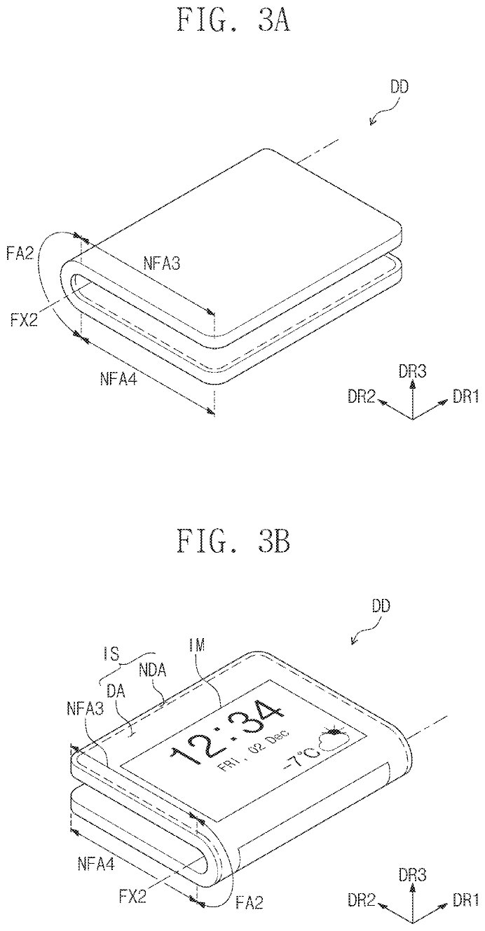

FIG. 3A is a schematic view illustrating a state in which the display device of FIG. 1 is in-folded along a second folding axis. FIG. 3B is a schematic view illustrating a state in which the display device of FIG. 1 is out-folded along the second folding axis.

Referring to FIGS. 3A and 3B, the display device DD may be in-folded or out-folded with respect to the second folding axis FX2. The second folding axis FX2 may extend along the first direction DR1, e.g., a short axis direction of the display device DD.

A plurality of areas may be defined in the display device DD according to an operation type. The plurality of areas may be divided into the second folding area FA2 and at least one non-folding area NFA1 or NFA2. The second folding area FA2 may be defined between two non-folding areas NFA1 and NFA2.

The second folding area FA2 may be an area that is folded with respect to the second folding axis FX2 to substantially define a curvature. The second folding area FA2 may be defined as an area that is folded along the second folding axis FX2 and extends in the first direction DR1.

According to an embodiment, the non-folding areas NFA1 and NFA2 may include a first non-folding area NFA1 and a second non-folding area NFA2. The third non-folding area NFA3 may be adjacent to a side of the second folding area FA2 in the second direction DR2, and the fourth non-folding area NFA4 may be adjacent to another side of the second folding area FA2 in the second direction DR2.

FIGS. 3A and 3B illustrate a structure in which the second folding area FA2 (as a single second folding area) is defined in the display device DD, but embodiments are not limited thereto. For example, a plurality of folding areas may be defined in the display device DD according to an embodiment.

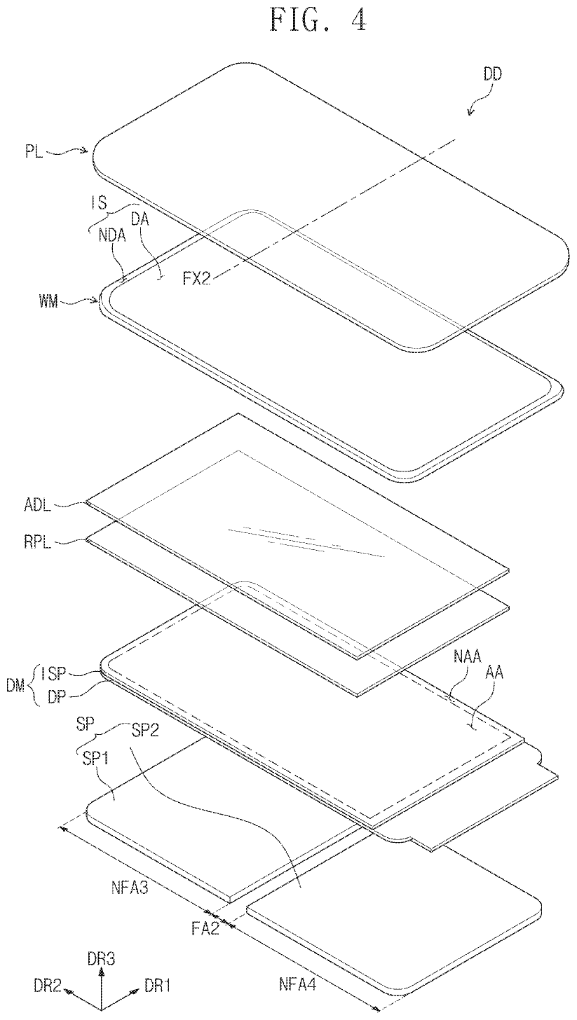

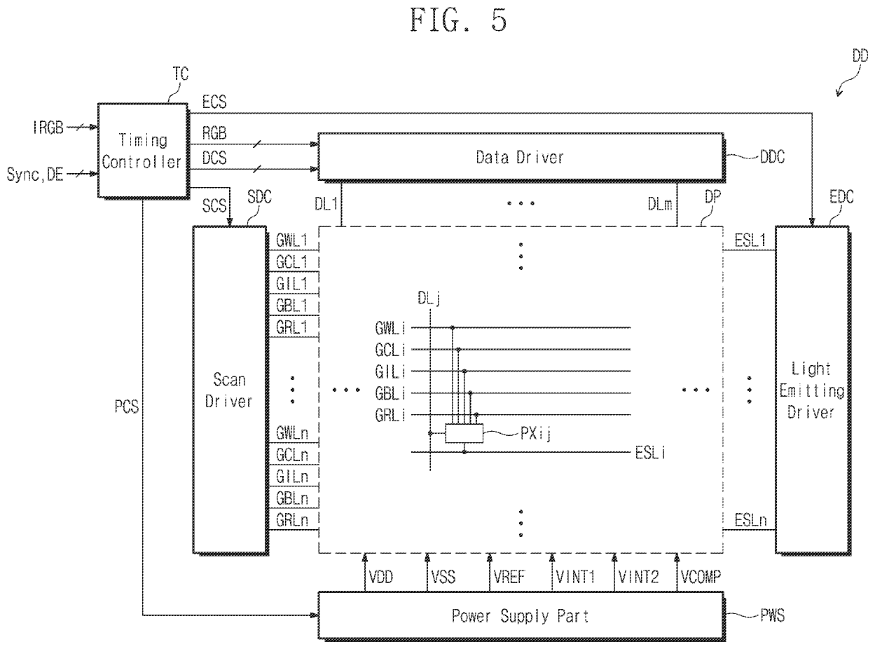

FIG. 4 is an exploded schematic perspective view of the display device according to an embodiment. Referring to FIG. 4, the display device DD according to an embodiment may include a display module DM displaying an image, a window WM disposed on the display module DM, and a protection layer PL disposed on the window WM.

The display module DM may include a display panel DP and an input sensing unit ISP. The display panel DP according to an embodiment may be an emission type display panel, but embodiments are not limited thereto. For example, the display panel DP may be an organic light emitting display panel or a quantum dot light emitting display panel. An emission layer of the organic light emitting display panel may include an organic light emitting material. An emission layer of the quantum dot light emitting display panel may include a quantum dot, a quantum rod, and the like. Hereinafter, the display panel DP is described as an organic light emitting display panel.

The display panel DP may be a flexible display panel. Thus, the display panel DP may be rolled, folded, or unfolded (e.g., entirely rolled, folded, or unfolded) with respect to the second folding axis FX2.

The input sensing unit ISP may be disposed (e.g., directly disposed) on the display panel DP. According to an embodiment, the input sensing unit ISP may be disposed on the display panel DP through a continuous process. In case that the input sensing unit ISP is directly disposed on the display panel DP, an adhesive film may not be disposed between the input sensing unit ISP and the display panel DP. However, embodiments are not limited thereto. The adhesive film ADL may be disposed between the input sensing unit ISP and the display panel DP. For example, the input sensing unit ISP may not be manufactured together with the display panel DP by the continuous process. Thus, after being manufactured by a process separate from the process of forming the display panel DP, the input sensing unit ISP may be fixed to a top surface (or upper surface) of the display panel DP by the adhesive film ADL.

The display panel DP may generate an image, and the input sensing unit ISP acquires coordinate information for a user's input (e.g., touch event).

The window WM may be disposed on the display module DM. The window WM may include an optically transparent insulating material. Thus, the image generated on the display module DM may pass through the window WM and thus be readily recognized by the user.

For example, the window WM may include a glass substrate or a synthetic resin film. In case that the window WM is thin glass, the thickness of the window WM may be about 80 μm or less, for example, about 30 μm, but the thickness of the window WM is not limited thereto.

In case that the window WM is the synthetic resin film, the window WM may include a polyimide (Pl) film or a polyethylene terephthalate (PET) film.

The window WM may have a single layer structure or a multilayered structure. For example, the window WM may include plastic films bonded to each other by using an adhesive or include a glass substrate and a plastic film, which are bonded to each other by using an adhesive. The window WM may be made of a flexible material. Thus, the window WM may be folded or unfolded with respect to the second folding axis FX2. For example, the window WM may be defined in shape together with deformation in shape of the display module DM.

The window WM may transmit the image transmitted from the display panel DP and also mitigate the external impact to prevent the display module DM from being damaged or malfunctioned by the external impact. The external impact may mean force applied from the outside, which is expressed as a pressure, stress, or the like, e.g., force that causes defects of the display module DM.

A protection layer PL may be disposed on the window WM. The protection layer PL may be a layer for protecting the window WM from an external impact and preventing scattering from occurring in case that the window WM is damaged.

One or more functional layers may be disposed between the display module DM and the window WM. For example, the functional layer according to an embodiment may be an anti-reflection layer RPL blocking external light reflection between the display module DM and the window WM. The anti-reflection layer RPL may prevent elements of the display module DM from being visually recognized at the outside by the external light incident through a front surface of the display device DD. The anti-reflection layer RPL may include a phase retarder and/or a polarizer. The phase retarder may be a film type or liquid crystal coating type retarder and may include a λ/2 retarder and/or a λ retarder. The polarizer may also be formed in a film type or liquid crystal coating type polarizer. The film type may include an elongation-type synthetic resin, and the liquid crystal coating type may include liquid crystals that are arranged in a certain arrangement. The phase retarder and the polarizer may be implemented as one polarizing film. The display device DD according to an embodiment may further include a protective film disposed above or under the anti-reflection layer RPL.

The anti-reflection layer RPL may be disposed on the input sensing unit ISP. For example, the anti-reflection layer RPL may be disposed between the input sensing unit ISP and the window WM. The anti-reflection layer RPL and the window WM may be coupled to each other through an adhesive film ADL. For example, an adhesive film for fixing the anti-reflection layer RPL to the input sensing unit ISP may be further disposed between the input sensing unit ISP and the anti-reflection layer RPL.

For example, the adhesive film ADL may include an optically clear adhesive film (OCA). However, the adhesive film ADL is not limited thereto and may include a typical adhesive or pressure-sensitive adhesive. For example, the adhesive film ADL may include an optically clear resin (OCR) or a pressure sensitive adhesive film (PSA).

The display module DM may display an image according to an electrical signal and transmit/receive information on an external input. The display module DM may be defined into an active area AA and a peripheral area NAA. The active area AA may be defined as an area that emits the image provided from the display module DM.

The peripheral area NAA may be adjacent to the active area AA. For example, the peripheral area NAA may surround the active area AA. However, this is an example. For example, the peripheral area NAA may have various shapes and is not limited to a specific embodiment. According to an embodiment, the active area AA of the display module DM may correspond to at least a portion of the display area DA.

The display device DD may further include a support plate SP disposed on the rear surface of the display module DM to support the display module DM. The support plate SP may include a rigid material. The support plate SP may include a material having an elastic modulus of about 10 GPa or more. For example, the support plate SP may include glass, but the material forming the support plate SP is not limited thereto. A thickness of the support plate SP may be about 50 μm to about 400 μm, but embodiments are not limited thereto.

The support plate SP may include the support plates SP1 and SP2 having the number corresponding to the number of non-folding areas NFA3 and NFA4. For example, the support plate SP may include a first support plate SP1 and a second support plate SP2, which is spaced apart from the first support plate SP1. The first and second support plates SP1 and SP2 may be disposed to correspond to the non-folding areas NFA3 and NFA4. For example, the first support plate SP1 may be disposed to correspond to the third non-folding area NFA3 of the display module DM, and the second support plate SP2 may be disposed to correspond to the fourth non-folding area NFA4 of the display module DM. In case that the display module DM is folded based on the second folding axis FX2, the first and second support plates SP1 and SP2 may be disposed to be spaced apart from each other in the second direction DR2.

The first and second support plates SP1 and SP2 may be spaced apart from each other to correspond to the second folding area FA2. The first and second support plates SP1 and SP2 may partially overlap the second folding area FA2. For example, a spaced distance between the first and second support plates SP1 and SP2 in the second direction DR2 may be less than a width of the second folding area FA2.

The support plate SP may further include a connection module that connects the first and second support plates SP1 and SP2 to each other. The connection module may include a hinge module or a multi-joint module.

Although a case in which the support plate SP includes two support plates SP1 and SP2 is illustrated, embodiments are not limited thereto. For example, in case that the number of second folding axes FX2 increases, the support plate SP may include support plates separated from each other with respect to the second folding axis FX2.

Although FIG. 4 illustrates a structure in which the support plate SP is separated into the first and second support plates SP1 and SP2, embodiments are not limited thereto. For example, the support plate SP may be formed in the form of a single plate disposed to correspond to the first and second non-folding areas NFA3 and NFA4 and the second folding area FA2. For example, the support plate SP may include holes defined by passing through the support plate SP disposed within the second folding area FA2.

A buffer film may be further disposed between the display module DM and the support plate SP. The buffer film may include a polymeric material. The buffer film may be a layer for absorbing an impact applied from the outside. The buffer film may be coupled to each of the display module DM and the support plate SP through an adhesive film.

FIG. 5 is a block diagram of the display device DD according to an embodiment. Referring to FIG. 5, the display device DD may include a display panel DP, panel drivers SDC, EDC, and DDC, a power supply PWS, and a timing controller TC. In an embodiment, the display panel DP is described as an emission-type display panel. The emission-type display panel may include an organic light-emitting display panel, an inorganic light-emitting display panel, or a quantum dot light-emitting display panel. In an embodiment to be described below, an organic light-emitting display panel will be described as an example. The panel driver may include a scan driver SDC, a light emitting driver EDC, and a data driver DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DL1 to DLm. The display panel DP may include pixels connected to the scan lines GWL1 to GWLn, GCL1 to GCLn, GIL1 to GILn, GBL1 to GBLn, and GRL1 to GRLn, the emission lines ESL1 to ESLn, and the data lines DL1 to DLm. Here, m and n are integers greater than 1.

For example, the pixel PXij disposed on an i-th horizontal line (or an i-th pixel row) and a j-th vertical line (or a j-th pixel column) may be connected to an i-th first scan line GWLi (or write scan line), an i-th second scan line GCLi (or compensation scan line), an i-th third scan line GILi (or first initialization scan line), an i-th fourth scan line GBLi (or second initialization scan line), an i-th fifth scan line GRLi (or reset scan line), a j-th data line DLj, and an i-th emission line ESLi. Here, i and j may be integers greater than 1.

The pixel PXij may include light emitting elements, transistors, and capacitors. The pixel PXij may receive a first power voltage VDD, a second power voltage VSS, a third power voltage VREF (or reference voltage), a fourth power voltage VINT1 (or first initialization voltage), a fifth power voltage VINT2 (or second initialization voltage), and a sixth power voltage VCOMP (or compensation voltage) through the power supply PWS.

A voltage value of each of the first power voltage VDD and the second power voltage VSS is set so that current may flow through the light emitting element to emit light. For example, the first power voltage VDD may be set to a voltage higher than the second power voltage VSS.

The third power voltage VREF may be a voltage for initializing a gate of a driving transistor formed in the pixel PXij. The third power voltage VREF may be used to implement a certain grayscale by using a voltage difference with a data signal. For example, the third power voltage VREF may be set to a certain voltage within a voltage range of the data signal.

The fourth power voltage VINT1 may be a voltage for initializing a capacitor formed in the pixel PXij. The fourth power voltage VINT1 may be set to a voltage lower than the third power voltage VREF. For example, the fourth power voltage VINT1 may be set to a voltage lower than a difference between the third power voltage VREF and the threshold voltage of the driving transistor. However, embodiments are not limited thereto.

The fifth power voltage VINT2 may be a voltage for initializing a cathode of the light emitting element formed in the pixel PXij. The fifth power voltage VINT2 may be set to a voltage lower than the first power voltage VDD or the fourth power voltage VINT1 or may be set to a voltage that is similar to or equal to the third power voltage VREF, but embodiments are not limited thereto. The fifth power voltage VINT2 may be set to a voltage that is similar to or equal to the first power voltage VDD.

The sixth power voltage VCOMP may supply certain current to the driving transistor to compensate for a threshold voltage of the driving transistor.

In FIG. 5, all of the first to sixth power voltages VDD, VSS, VREF, VINT1, VINT2, and VCOMP may be supplied from the power supply PWS, but embodiments are not limited thereto. For example, all of the first power voltage VDD and the second power voltage VSS may be supplied regardless of the structure of the pixel PXij, and at least one voltage of the third power voltage VREF, the fourth power voltage VINT1, the fifth power voltage VINT2, and the sixth power voltage VCOMP may not be supplied to correspond to the structure of the pixel PXij.

In an embodiment, signal lines connected to the pixel PXij may be set variously to correspond to the circuit structure of the pixel PXij.

The scan driver SDC may receive a first control signal SCS from a timing controller TC and may supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn based on the first control signal SCS.

The scan signal may be set to a voltage at which the transistors receiving the scan signal are turned on. For example, a scan signal supplied to a P-type transistor may be set to a logic low level, and a scan signal supplied to an N-type transistor may be set to a logic high level. Hereinafter, the meaning of “that the scan signal is supplied” may be understood as that the scan signal is supplied with a logic level that turns on the transistor controlled thereby.

In FIG. 5, for convenience of description, the scan driver SDC is illustrated as a single configuration, but embodiments are not limited thereto. According to an embodiment, scan drivers may be provided to supply the scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The light emitting driver EDC may supply a light emitting signal to the emission lines ESL1 to ESLn based on a second control signal ECS. For example, the light emitting signal may be sequentially supplied to the emission lines ESL1 to ESLn.

The transistors connected to the emission lines ESL1 to ESLn may be formed as N-type transistors. For example, the light emitting signal supplied to the emission lines ESL1 to ESLn may be set to a gate-off voltage. The transistors receiving the light emitting signal may be turned off in case that the light emitting signal is supplied and may be turned on in other cases.

The second control signal ECS may include an emission start signal and clock signals, and the light emitting driver EDC may sequentially shift the emission start signal having a pulse form based on the clock signals so as to be implemented as an axis resistor that sequentially generates and outputs the emission signal having pulse form.

The data driver DDC may receive the third control signal DCS and image data RGB from the timing controller TC. The data driver DDC may convert the digital image data RGB into an analog data signal (e.g., a data signal). The data driver DDC may supply data signals to the data lines DL1 to DLm in response to the third control signal DCS.

The third control signal DCS may include a data enable signal, a horizontal start signal, and a data clock signal, which instruct an output of a valid data signal. For example, the data driver DDC may include a shift register that generates a sampling signal by shifting the horizontal start signal in synchronization with the data clock signal, a latch that latches image data RGB in response to a sampling signal, a digital-to-analog converter (or decoder) that converts the latched image data (e.g., digital data) into analog data signals, and buffers (or amplifiers) that output data signals to the data lines DL1 to DLm.

The power supply PWS may supply the first power voltage VDD, the second power voltage VSS, and the third power voltage VREF, which drive the pixel PXij, to the display panel DP. For example, the power supply PWS may supply at least one of the fourth power voltage VINT1, the fifth power voltage VINT2, and the sixth power voltage VCOMP to the display panel DP.

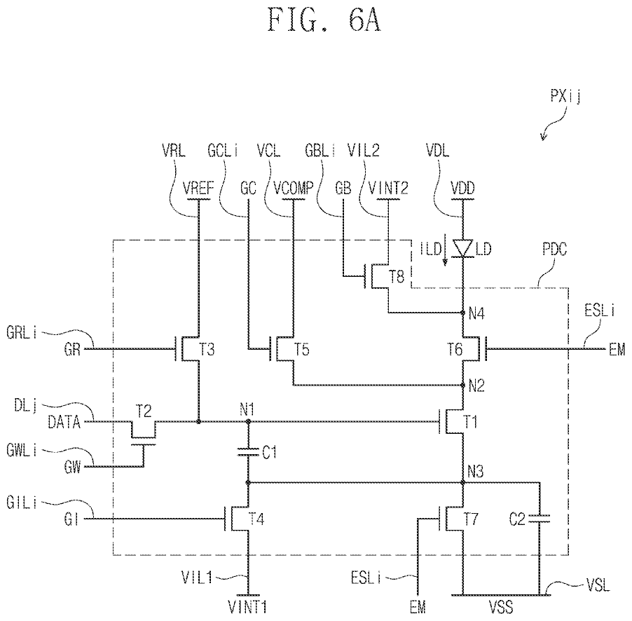

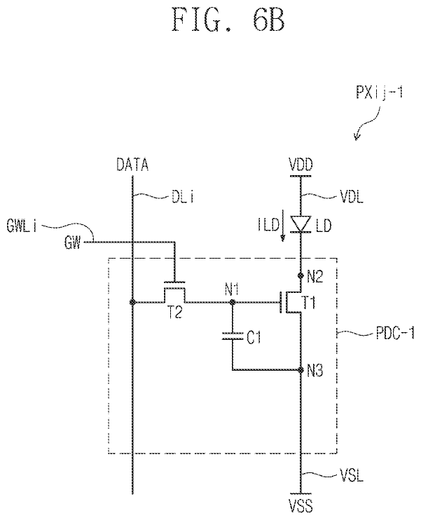

For example, the power supply PWS may supply the first power voltage VDD, the second power voltage VSS, the third power voltage VREF, the fourth power voltage VINT1, the fifth power voltage VINT2, and the sixth power voltage VCOMP to the display panel DP via a first power line (or first power line VDL in FIG. 6A), a second power line (or second power line VSL in FIG. 6A), a third power line (or reference voltage line VRL in FIG. 6A), a fourth power line (or first initialization voltage line VIL1 in FIG. 6A), a fifth power line (or a second initialization voltage line VIL2 in FIG. 6A), and a sixth power line (or compensation voltage line VCL in FIG. 6A).

The power supply PWS may be implemented as a power management integrated circuit, but embodiments are not limited thereto.

The timing controller TC may generate the first control signal SCS, the second control signal ECS, the third control signal DCS, and the fourth control signal PCS based on an input image data IRGB, a synchronization signal Sync (e.g., vertical synchronization signal, a horizontal synchronization signal, etc.), a data enable signal DE, clock signal, etc. The first control signal SCS may be supplied to the scan driver SDC, the second control signal ECS may be supplied to the light emitting driver EDC, and the third control signal DCS may be supplied to the data driver DDC, and the fourth control signal PCS may be supplied to the power supply PWS. The timing controller TC may rearrange the input image data IRGB to correspond to the arrangement of the pixels PXij in the display panel DP, thereby generating the image data RGB (or frame data).

The scan driver SDC, the light emitting driver EDC, the data driver DDC, the power supply PWS, and/or the timing controller TC may be provided on (e.g., directly on) the display panel DP or provided in the form of a separate driving chip so as to be connected to the display panel DP. For example, at least two of the scan driver SDC, the light emitting driver EDC, the data driver DDC, the power supply PWS, and the timing controller TC may be formed as a driving chip (e.g., a single driving chip). For example, the data driver DDC and the timing controller TC may be formed as a driving chip (e.g., a single driving chip).

In the above, the display device DD according to an embodiment has been described with reference to FIG. 5, but embodiments are not limited thereto. The signal lines may be further added or omitted according to the configuration of the pixels. For example, the connection relationship between one pixel and the signal lines may be changed. In case that one of the signal lines is omitted, another signal line may replace the omitted signal line.

FIGS. 6A and 6B are schematic diagrams of equivalent circuits of a pixel according to an embodiment. In FIGS. 6A and 6B, the equivalent circuits of the pixels PXij and PXij−1 connected to the i-th first scan line GWLi (hereinafter, referred to as a first scan line) and connected to the j-th data line DLj (hereinafter, referred to as a data line) are illustrated as an example.

As illustrated in FIG. 6A, the pixel PXij may include a light emitting element LD and a pixel driver PDC. The light emitting element LD may be connected to the first power line VDL and the pixel driver PDC.

The pixel driver PDC may be connected to the scan lines GWLi, GCLi, GILi, GBLi, and GRLi, the data line DLj, the emission line ESLi, and the power voltage lines VDL, VSL, VIL1, VIL2, VRL, and VCL. The pixel driver PDC may include first to eighth transistors T1, T2, T3, T4, T5, T6, T7, and T8, a first capacitor C1, and a second capacitor C2. Hereinafter, a case in which each of the first to eighth transistors T1, T2, T3, T4, T5, T6, T7, and T8 is an N-type will be described as an example. However, embodiments are not limited thereto, and some of the first to eighth transistors T1 to T8 may be N-type transistors, others may be P-type transistors, and each of the first to eighth transistors T1 to T8 may be a P-type transistor, but embodiments are not limited thereto.

A gate of the first transistor T1 may be connected to a first node N1. A first electrode of the first transistor T1 may be connected to a second node N2, and a second electrode of the first transistor T1 may be connected to a third node N3. The first transistor T1 may be a driving transistor. The first transistor T1 may control driving current ILD flowing from the first power line VDL to the second power line VSL via the light emitting element LD in response to a voltage of the first node N1. For example, the first power voltage VDD may be set to a voltage having a potential higher than that of the second power voltage VSS.

In the description, “that is electrically connected between the transistor and the signal line or between the transistor and the transistor” means “that a source, a drain, and a gate of the transistor have an integral shape with the signal line or are connected through a connection electrode.”.

The second transistor T2 may include a gate connected to the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi. The second transistor T2 may be turned on in case that the write scan signal GW is supplied to the write scan line GWLi to electrically connect the data line DLj to the first node N1.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In an embodiment, the gate of the third transistor T3 may receive a reset scan signal GR through the i-th fifth scan line GRLi (hereinafter, referred to as a fifth scan line). The third transistor T3 may be turned on in case that the reset scan signal GR is supplied to the i-th fifth scan line GRLi to provide the reference voltage VREF to the first node N1.

The fourth transistor T4 may be connected between the third node N3 and the first initialization voltage line VIL1. The first electrode of the fourth transistor T4 may be connected to the third node N3, and the second electrode of the fourth transistor T4 may be connected to the first initialization voltage line VIL1 providing the first initialization voltage VINT1. The fourth transistor T4 may be referred to as a first initialization transistor. A gate of the fourth transistor T4 may receive a first initialization scan signal GI through the i-th third scan line GILi (hereinafter, referred to as a third scan line). The fourth transistor T4 may be turned on in case that the first initialization scan signal GI is supplied to the first initialization scan line GILi to supply the first initialization voltage VINT1 to the third node N3.

The fifth transistor T5 may be connected between the compensation voltage line VCL and the second node N2. The first electrode of the fifth transistor T5 may receive the compensation voltage VCOMP through the compensation voltage line VCL, and the second electrode of the fifth transistor T5 may be connected to the second node N2 so as to be electrically connected to the first electrode of the transistor T1. A gate of the fifth transistor T5 may receive a compensation scan signal GC through the i-th second scan line GCLi (hereinafter, referred to as a second scan line). The fifth transistor T5 may be turned on in case that the compensation scan signal GC is supplied to the compensation scan line GCLi to provide the compensation voltage VCOMP to the second node N2, and thus, a threshold voltage of the transistor T1 may be compensated during a compensation period.

The sixth transistor T6 may be connected between the first transistor T1 and the light emitting element LD. For example, a gate of the sixth transistor T6 may receive the light emitting signal EM through the i-th emission line ESLi (hereinafter, referred to as an emission line). The first electrode of the sixth transistor T6 may be connected to a cathode of the light emitting element LD through the fourth node N4, and the second electrode of the sixth transistor T6 may be connected to the first electrode of the first transistor T1 through the second node N2. The sixth transistor T6 may be referred to as a first emission control transistor. In case that the light emitting signal EM is supplied to the emission line ESLi, the sixth transistor T6 may be turned on to electrically connect the light emitting element LD to the first transistor T1.

The seventh transistor T7 may be connected between the second power line VSL and the third node N3. The first electrode of the seventh transistor T7 may be connected to the second electrode of the first transistor T1 through the third node N3, and the second electrode of the seventh transistor T7 may receive the second power voltage VSS through the second power line VSL. A gate of the seventh transistor T7 may be electrically connected to the emission line ESLi. The seventh transistor T7 may be referred to as a second emission control transistor. In case that the light emitting signal EM is supplied to the emission line ESLi, the seventh transistor T7 may be turned on to electrically connect the second electrode of the first transistor T1 to the second power line VSL.

In an embodiment, the sixth transistor T6 and the seventh transistor T7 may be connected to the same emission line ESLi and turned on by the same light emitting signal EM, but this is an example. For example, the sixth transistor T6 and the seventh transistor T7 may be independently turned on by different signals that are distinguished from each other. For example, in the pixel driver PDC according to an embodiment, either the sixth transistor T6 or the seventh transistor T7 may be omitted.

The eighth transistor T8 may be connected between the second initialization voltage line VIL2 and the fourth node N4. For example, the eighth transistor T8 may include a gate connected to the i-th fourth scan line GBLi (hereinafter, referred to as a fourth scan line), a first electrode connected to the second initialization voltage line VIL2, and a second electrode connected to a fourth node N4. The eighth transistor T8 may be referred to as a second initialization transistor. The eighth transistor T8 may supply the second initialization signal VINT2 to the second node N4 corresponding to the cathode of the light emitting element LD in response to the second initialization scan line GB transmitted through the second initialization scan line GBLi. The cathode of the light emitting element LD may be initialized by the second initialization voltage VINT2.

In an embodiment, some of the second to eighth transistors T2, T3, T4, T5, T6, T7, and T8 may be simultaneously turned on through the same scan signal. For example, the eighth transistor T8 and the fifth transistor T5 may be simultaneously turned on through the same scan signal. For example, the eighth transistor T8 and the fifth transistor T5 may operate by the same compensation scan signal GC. The eighth transistor T8 and the fifth transistor T5 may be simultaneously turned on/off by the same compensation scan signal GC. For example, the compensation scan line GCLi and the second initialization scan line GBLi may be substantially formed as a single scan line. Thus, the initialization of the cathode of the light emitting element LD and the compensation of the threshold voltage of the first transistor T1 may be performed at the same timing. However, this is an example and embodiments are not limited thereto.

For example, according to an embodiment, the initialization of the cathode of the light emitting element LD and the compensation of the threshold voltage of the first transistor T1 may be performed by applying the same power voltage. For example, the compensation voltage line VCL and the second initialization voltage line VIL2 may be substantially formed as a single power voltage line. For example, the cathode initialization operation and the compensation operation of the driving transistor may be performed at a power voltage (e.g., a single power voltage), and thus, a design of the driver may be simplified. However, this is an example, but embodiments are not limited thereto.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. For example, an electrode of the second capacitor C2 may be connected to the second power line VSL receiving the second power voltage VSS, and another electrode of the second capacitor C2 may be connected to the third node N3. The second capacitor C2 may store a charge corresponding to a voltage difference between the second power voltage VSS and the second node N2. The second capacitor C2 may be referred to as a hold capacitor. The second capacitor C2 may have a storage capacity greater than that of the first capacitor C1. Thus, the second capacitor C2 may minimize a voltage change of the third node N3 in response to a voltage change of the first node N1.

In an embodiment, the light emitting element LD may be connected to the pixel driver PDC through the fourth node N4. The light emitting element LD may include an anode connected to the first power line VDL and a cathode opposite to the anode. In an embodiment, the light emitting element LD may be connected to the pixel driver PDC through the cathode. For example, in the pixel PXij according to an embodiment, a connection node at which the light emitting element LD and the pixel driver PDC are connected may be the fourth node N4, and the fourth node N4 may correspond to a connection node between the first electrode of the sixth transistor T6 and the cathode of the light emitting element LD. Thus, a potential of the fourth node N4 may substantially correspond to a potential of the cathode of the light emitting element LD.

For example, the anode of the light emitting element LD may be connected to the first power line VDL to receive the first power voltage VDD, which is a constant voltage, and the cathode may be connected to the first transistor T1 through the sixth transistor T6. For example, in an embodiment in which the first to eighth transistors T1 to T8 are N-type transistors, the potential of the third node N3 corresponding to the source of the first transistor T1, which is the driving transistor, may not be directly affected by the characteristics of the light emitting element LD. Therefore, although the light emitting element LD is deteriorated, an effect on the transistors of the pixel driver PDC, and a gate-source voltage Vgs of the driving transistor, may be reduced. For example, since an amount of change in driving current due to the deterioration of the light emitting element LD may be reduced, afterimage defects of the display panel DP according to an increase in use time may be reduced, and a lifespan of the display panel DP may be improved.

In another example, as illustrated in FIG. 6B, the pixel PXij−1 may include a pixel driver PDC−1 including two transistors T1 and T2 and one capacitor C1. The pixel driver PDC−1 may be connected to the light emitting element LD, the write scan line GWLi, the data line DLj, and the second power line VSL. The pixel driver PDC−1 illustrated in FIG. 6B may correspond to a case in which the third to eighth transistors T3 to T8 and the second capacitor C2 are omitted in the pixel driver PDC illustrated in FIG. 6A.

Each of the first and second transistors T1 and T2 may be an N-type transistor or a P-type transistor. In an embodiment, each of the first and second transistors T1 and T2 will be described as an N-type transistor.

The first transistor T1 may include a gate connected to the first node N1, a first electrode connected to the second node N2, and a second electrode connected to the third node N3. The second node N2 may be a node connected to a side of the first power line VDL, and the third node N3 may be a node connected to a side of the second power line VSL. The first transistor T1 may be connected to the light emitting element LD through the second node N2 and connected to the second power line VSL through the third node N3. The first transistor T1 may be a driving transistor.

The second transistor T2 may include a gate receiving the write scan signal GW through the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi.

The capacitor C1 may include an electrode connected to the first node N1 and an electrode connected to the third node N3. The capacitor C1 may store a data signal DATA transmitted to the first node N1.

The light emitting element LD may include an anode and a cathode. In an embodiment, the anode of the light emitting element LD may be connected to the first power line VDL, and the cathode may be connected to the pixel driver PDC−1 through the second node N2. In an embodiment, the cathode of the light emitting element LD may be connected to the first transistor T1. The light emitting element LD may emit light in response to an amount of current flowing through the first transistor T1 of the pixel driver PDC−1.

In an embodiment in which the first and second transistors T1 and T2 are the N-type transistors, the second node N2 at which the cathode of the light emitting element LD and the pixel driver PDC−1 are connected may correspond to the drain of the transistor T1. For example, a change in gate-source voltage Vgs of the first transistor T1 caused by the light emitting element LD may be prevented. Thus, since an amount of change in driving current due to the deterioration of the light emitting element LD may be reduced, afterimage defects of the display panel according to an increase in use time may be reduced, and a lifespan of the display panel may be improved.

FIGS. 6A and 6B illustrate circuits for the pixel drivers PDC and PDC−1 according to an embodiment, and in the display panel according to an embodiment, in case that the circuit is connected to the cathode of the light emitting element LD, the number or arrangement of transistors and the number or arrangement of capacitors may be designed in various manners and are not limited thereto.

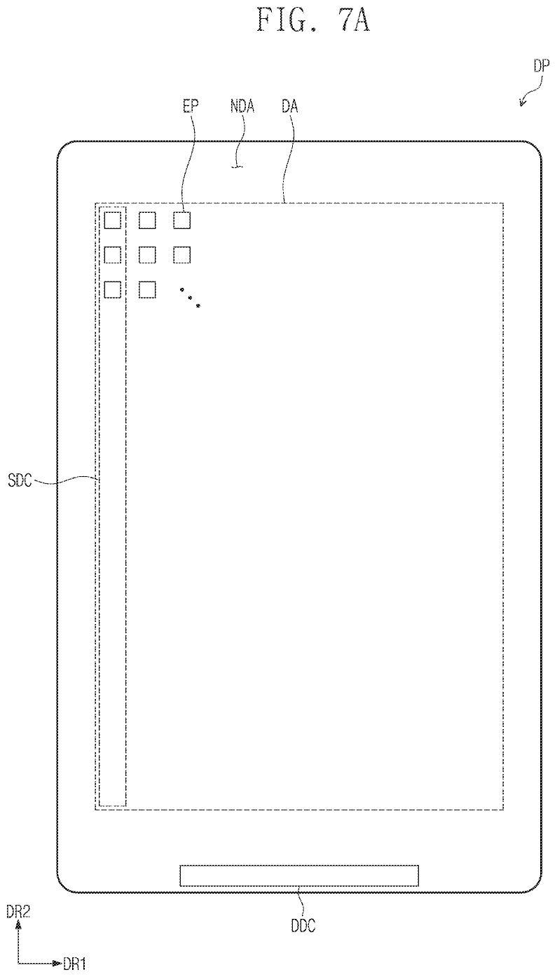

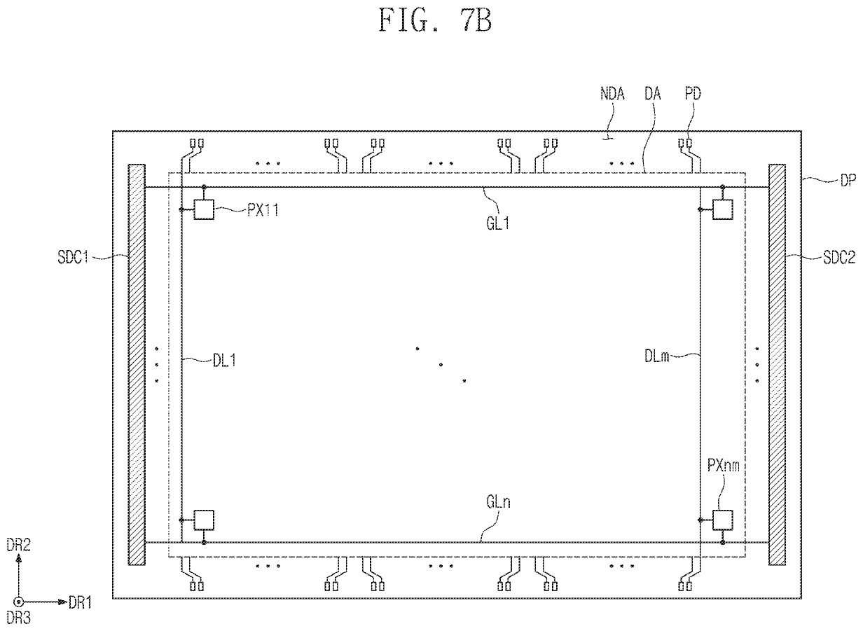

FIGS. 7A and 7B are schematic plan views of the display panel according to an embodiment. In each of FIGS. 7A and 7B, some components are omitted. Hereinafter, the disclosure will be described with reference to FIGS. 7A and 7B. Referring to FIG. 7A, the display panel DP according to an embodiment may be divided into a display area DA and a peripheral area NDA (or non-display area). The display area DA may include light emitting parts EP.

The light emitting parts EP may be areas that respectively emit light by the pixels PXij (see FIG. 6A). For example, each of the light emitting parts EP may correspond to a light emitting opening OP-PDL to be described below.

The non-display area NDA may be disposed adjacent to the display area DA. In an embodiment, the non-display area NDA may have a shape surrounding an edge portion of the display area DA. However, this is an example, and the non-display area NDA may be disposed at a side of the display area DA or may be omitted, but embodiments are not limited thereto.

In an embodiment, the scan driver SDC and the data driver DDC (see FIG. 5) may be mounted on the display panel DP. In an embodiment, the scan driver SDC may be disposed on the display area DA, and the data driver DDC may be disposed on the non-display area NDA. The scan driver SDC may overlap at least a portion of the light emitting parts EP disposed on the display area DA in a plan view. As the scan driver SDC is disposed on the display area DA, a surface area of the non-display area NDA may be reduced as compared to the display panel, in which the scan driver is disposed on the peripheral area, and thus, a display device having a thin bezel may be readily implemented.

Unlike illustrated in FIG. 7A, the scan driver SDC may be formed as two portions that are distinguished from each other. The two scan drivers SDC may be spaced apart from each other in a left to right direction with respect to a center portion of the display area DA. In another example, the scan drivers SDC may be provided in a larger number than two, but embodiments are not limited thereto.

FIG. 7A illustrates an example of the display panel, and the data driver DDC may be disposed on the display area DA. For example, some of the light emitting parts EP disposed on the display area DA may overlap the data driver DDC in a plan view.

In an embodiment, the data driver DDC may be provided in the form of a separate driving chip independent of the display panel DP and be connected to the display panel DP. However, this is an example, and the data driver DDC may be formed in the same process as the scan driver SDC to form the display panel DP, but embodiments are not limited thereto.

As illustrated in FIG. 7B, the display panel DP may have a shape in which a length corresponding to the first direction DR1 is greater than a length corresponding to the second direction DR1. In an embodiment, the display panel DP may include scan drivers SDC1 and SDC2. The scan drivers SDC1 and SDC2 are illustrated as including a first scan driver SDC1 and a second scan driver SDC2, which are spaced apart from each other in the first direction DR1. For example, pixels PX11 to PXnm may be arranged in the display area DA.

The first scan driver SDC1 may be connected to some of the scan lines GL1 to GLn, and the second scan driver SDC2 may be connected to other portions of the scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

FIG. 7B illustrates pads PD of the data lines DL1 to DLm for descriptive convenience. The pads PD may be formed at end portions of the data lines DL1 to DLm. The data lines DL1 to DLm may be connected to the data driver DDC (see FIG. 3A) through the pads PD.

According to an embodiment, the pads PD may be divided and arranged at positions on the non-display area NDA, which are spaced apart from each other with the display area DA therebetween. For example, some of the pads PD may be disposed at an upper side, e.g., at a side adjacent to the first scan line GL1 among the scan lines GL1 to GLn, and other portions of the pads PD may be disposed at a lower side, e.g., at a side adjacent to the last scan line GLn among the scan lines GL1 to GLn. In an embodiment, the pads PD connected to the odd-numbered data lines among the data lines DL1 to DLm may be disposed at the upper side, and the pads PD connected to the even-numbered data lines among the data lines DL1 to DLm may be disposed at the lower side.

For example, the display panel DP may include upper data drivers connected to the pads PD disposed at the upper side and/or lower data drivers connected to the pads PD disposed at the lower side. However, this is an example, and the display panel DP may include a single upper data driver connected to the pads PD disposed at the upper side and/or a single lower data driver connected to the pads PD disposed at the lower side. For example, the pads PD according to an embodiment may be disposed at only one side of the display panel DP and thus connected to a single data driver, and embodiments are not limited thereto.

As described above with reference to FIG. 7A, in the display panel DP in FIG. 3B, the scan driver and/or a data driver may also be disposed on the display area DA, and thus, some of the light emitting parts disposed on the display area DA may overlap the scan driver and/or the data driver in a plan view.

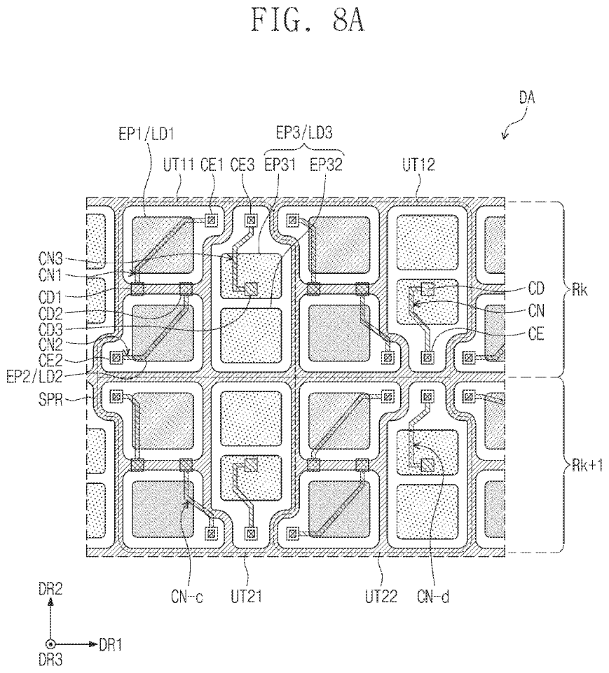

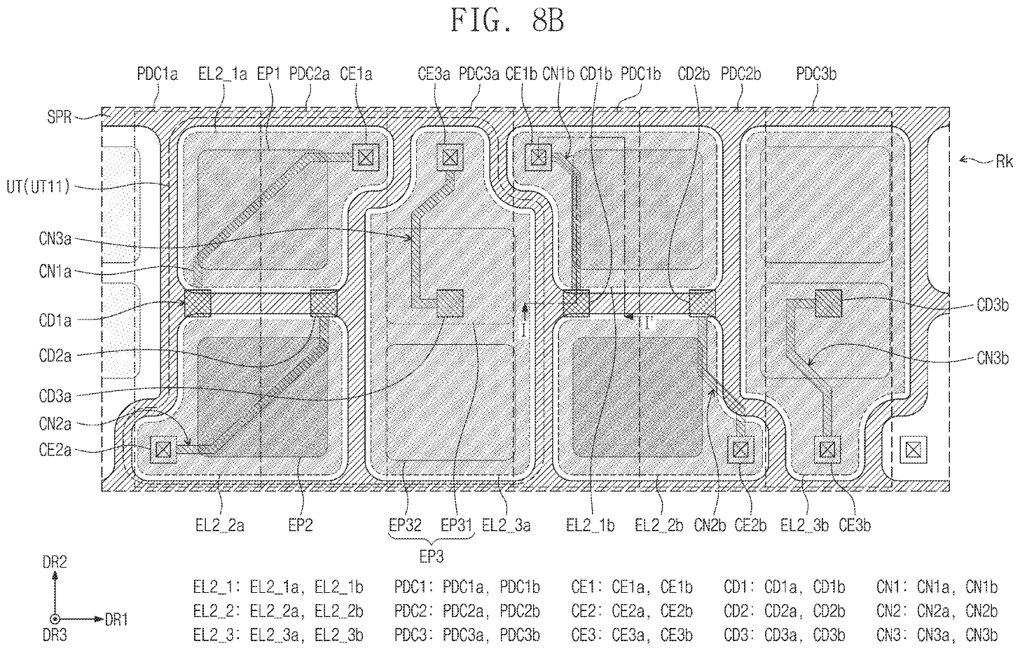

FIGS. 8A and 8B is schematic plan views of the display panel according to an embodiment. FIG. 8A illustrates an area on which a total of four light emitting parts in two rows and two columns are disposed, and FIG. 8B illustrates an enlarged schematic view of a partial area illustrated in FIG. 8A. Hereinafter, an embodiment will be described with reference to FIGS. 8A and 8B.

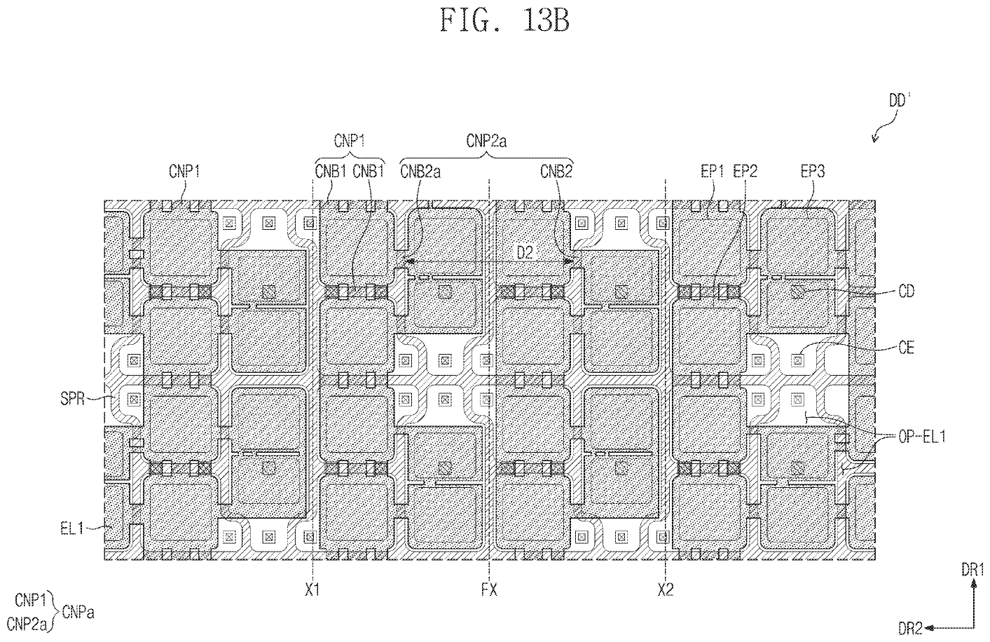

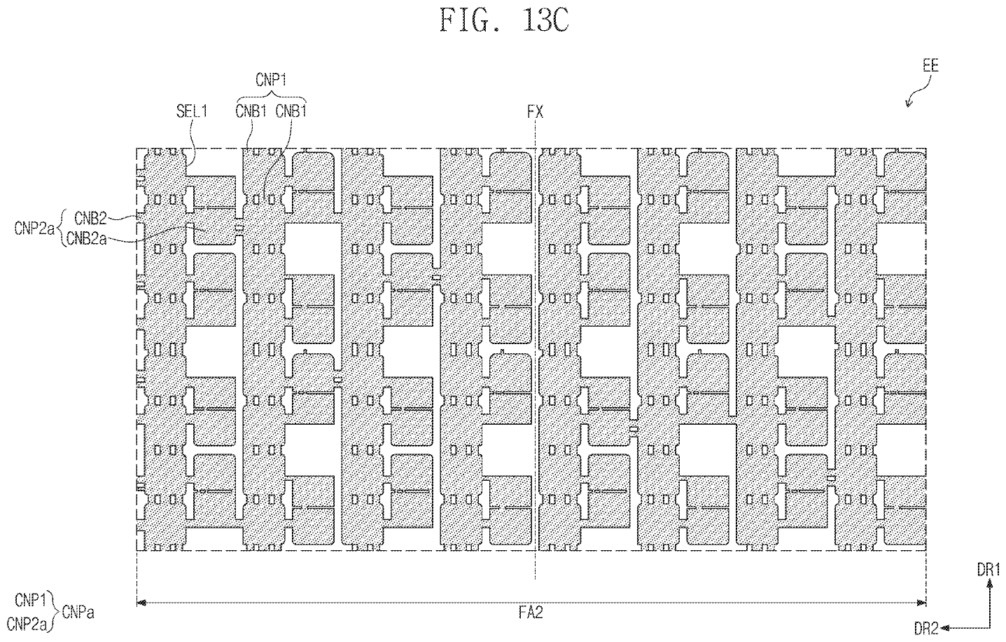

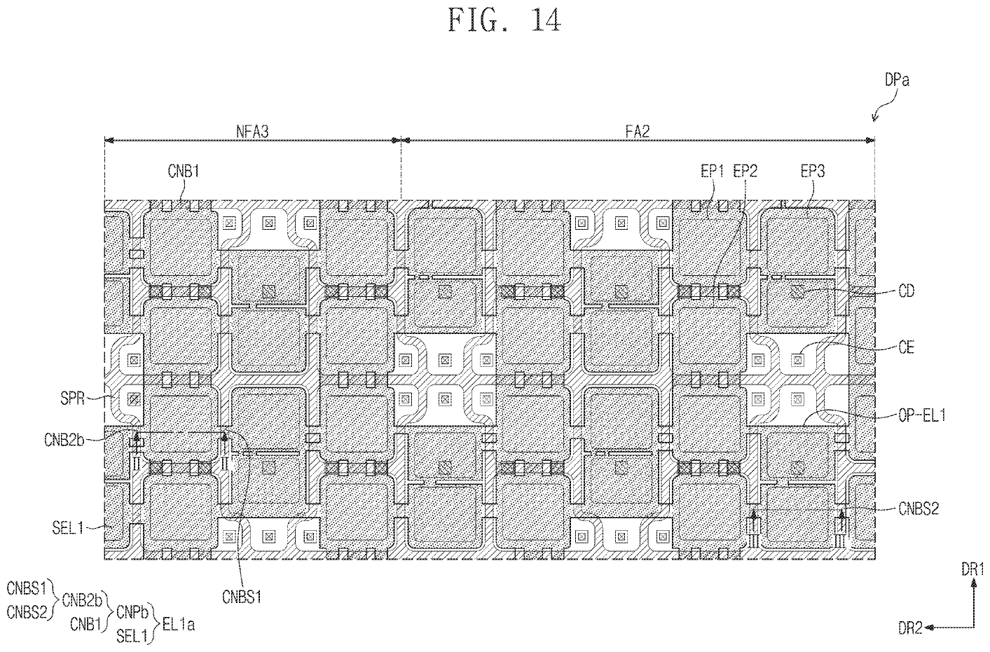

FIG. 8A illustrates light emitting parts UT11, UT12, UT21, and UT22 in two rows and two columns. The light emitting parts in a first row Rk may include the light emitting parts of a first row first column light emitting part UT11 and a first row second column light emitting part UT12, and the light emitting parts in a second row Rk+1 may include the light emitting parts of a second row first column light emitting part UT21 and a second row second column light emitting part UT22. FIG. 8B illustrates the light emitting parts in the first row Rk. FIGS. 8A and 8B illustrate a separator SPR, light emitting parts EP1, EP2, and EP3 disposed on an area partitioned by the separator SPR, connection lines CN1, CN2, and CN3, and second electrodes EL2_1, EL2_2, and EL2_3 among components of the display panel. The first electrode EL1 (see FIG. 13) will be described below.

As described above, each of the light emitting parts EP1, EP2, and EP3 may correspond to a light emitting opening OP-PDL to be described below. For example, each of the light emitting parts EP1, EP2, and EP3 may be an area from which light is emitted by the above-described light emitting device and may correspond to a unit constituting an image displayed on the display panel DP. For example, each of the light emitting parts EP1, EP2, and EP3 may correspond to an area defined by the light emitting opening OP-PDL (see, e.g., FIG. 5) to be described below, e.g., an area defined by a bottom surface (or lower surface) of the light emitting opening OP-PDL.

The light emitting parts EP1, EP2, and EP3 may include a first light emitting part EP1, a second light emitting part EP2, and a third light emitting part EP3. The first light emitting part EP1, the second light emitting part EP2, and the third light emitting part EP3 may emit light having colors different from each other. Thus, the first light emitting element LD1 of the first light emitting part EP1, the second light emitting element LD2 of the second light emitting part EP2, and the third light emitting element of the third light emitting part EP3 may emit light having different colors. For example, the first light emitting part EP1 may emit red light, the second light emitting part EP2 may emit green light, and the third light emitting part EP3 may emit blue light, but the combination of the colors is not limited thereto. For example, at least two or more of the light emitting parts EP1, EP2, and EP3 may emit light having the same color. For example, all of the first to third light emitting parts EP1, EP2, and EP3 may emit blue light or emit white light.

In the light emitting parts EP1, EP2, and EP3, the third light emitting part EP3 displaying light emitted by the third light emitting part EP3 may include two sub light emitting parts EP31 and EP32 which are spaced apart from each other in the second direction DR2. However, this is an example, and the third light emitting part EP3 may be formed in a single pattern layer having an integral shape, like the other light emitting parts EP1 and EP2 and may include sub light emitting parts, in which at least one of other light emitting parts EP1 and EP2 are spaced apart from each other, but embodiments are not limited thereto.

In an embodiment, the light emitting parts in the first row Rk may include light emitting parts in which the first row first column light emitting parts UT11 and the first row second column light emitting parts UT12 are repeatedly arranged. The light emitting parts in the second row Rk+1 may include light emitting parts having a shape and arrangement in which the light emitting parts in the first row Rk are axisymmetric with respect to an axis parallel to the first direction DR1. Thus, the shape and arranged shape of the light emitting parts of the first row first column light emitting part UT11 and the first row second column light emitting part UT12 and the connection parts of the connection lines, which are axisymmetric with respect to the axis parallel to the first direction DR1, may correspond to the light emitting parts of the second row first column light emitting part UT21 and the second row second column light emitting part UT22 and the connection parts of connection lines.

Hereinafter, the first row first column light emitting part UT11 will be described. FIG. 8B illustrates second electrodes EL2_1 (e.g., EL2_1a and EL2_1b), EL2_2 (e.g., EL2_2a and EL2_2b), and EL2_3 (e.g., EL2_3a and EL2_3b), pixel drivers PDC, and connection lines CN for descriptive convenience. The second electrodes EL2_1, EL2_2, and EL2_3 may be electrically disconnected from each other by being separated from each other by the separator SPR. In an embodiment, a light emitting part UT (as a single light emitting part) may include three light emitting parts EP1, EP2, and EP3. Thus, the light emitting part UT may include three second electrodes EL2_1, EL2_2, and EL2_3 (hereinafter, referred to as first to third cathodes), three pixel drivers PDC1 (e.g., PDCla and PDC1b), PDC2 (e.g., PDC2a and PDC2b), and PDC3 (e.g., PDC3a and PDC3b), and three connection lines CN1 (e.g., CNla and CN1b), CN2 (e.g., CN2a and CN2b), and CN3 (e.g., CN3a and CN3b). However, this is an example, and the number and arrangement of the light emitting parts UT may be designed in various manners, but embodiments are not limited thereto.

The first to third pixel drivers PDC1, PDC2, and PDC3 may be electrically connected to the light emitting elements LD1, LD2, and LD3 of the first to third light emitting parts EP1, EP2, and EP3, respectively. In the description, “connected” includes not only a case of being physically connected by direct contact, but also a case of being electrically connected.

For example, as illustrated in FIG. 8B, in each area on which the pixel drivers PDC1, PDC2, and PDC3 are defined in a plan view may correspond units in which the transistor and capacitor elements of the pixel driver PDC (see FIG. 6A) for driving the light emitting element of the pixel are repeatedly arranged.

The first to third pixel drivers PDC1, PDC2, and PDC3 may be sequentially disposed along the first direction DR1. The disposed positions of the first to third pixel drivers PDC1, PDC2, and PDC3 may be independently designed regardless of the positions or shapes of the first to third light emitting parts EP1, EP2, and EP3.

For example, the first to third pixel drivers PDC1, PDC2, and PDC3 may be designed to be disposed on an area defined by being partitioned by the separator, e.g., a position different from the position at which the first to third cathodes EL2_1, EL2_2, and EL2_3 are disposed or to have a surface area (or size) having a shape different from that of the first to third cathodes EL2_1, EL2_2, and EL2_3. In another example, the first to third pixel drivers PDC1, PDC2, and PDC3 may be designed to be disposed to overlap the positions at which the first to third light emitting parts EP1, EP2, and EP3 are present and to be disposed on an area defined by being partitioned by a separator, for example, in a shape having a surface area (or size) similar to that of the first to third cathodes EL2_1, EL2_2, and EL2_3.

In an embodiment, each of the first to third pixel drivers PDC1, PDC2, and PDC3 is illustrated in a rectangular shape, and each of the first to third light emitting parts EP1, EP2, and EP3 may have a surface area (or size) less than that of each of the first to third pixel drivers PDC1, PDC2, and PDC3 and a shape different from that of each of the first to third pixel drivers PDC1, PDC2, and PDC3, and the first to third cathodes EL2_1, EL2_2, and EL2_3 may be disposed at positions overlapping the first to third light emitting parts EP1, EP2, and EP3 and formed in irregular shapes.

Thus, as illustrated in FIG. 8B, the first pixel driver PDC1 may be disposed at a position that partially overlaps the first light emitting part EP1, the second light emitting part EP2, and other light emitting parts adjacent thereto. The second pixel driver PDC2 may be disposed at a position overlapping the first light emitting part EP1, the second light emitting part EP1, and the third light emitting part EP3. The third pixel driver PDC3 may be disposed at a position overlapping the third light emitting part EP3. This is an example, and the positions of the first to third pixel drivers PDC1, PDC2, and PDC3 may be designed in various shapes and arrangements independently of the light emitting parts EP1, EP2, and EP3, but embodiments are not limited thereto.

The connection line CN may be formed in plural that are spaced apart from each other. The connection line CN may electrically connect the pixel driver PDC to the light emitting element LD. For example, the connection line CN may correspond to the node (see reference symbol N4 in FIG. 6A or reference symbol N2 in FIG. 6B) at which the light emitting element LD is connected to the pixel driver PDC.

The connection line CN may include a first connection portion CE (or light emitting connection part), a second connection portion CD (or driving connection part), and an extension part extending from the light emitting connection part and electrically connecting the light emitting connection part to the driving connection part. The light emitting connection portion CE may be provided at a side of the connection line CN, and the driving connection part CD may be provided at another side of the connection line CN.

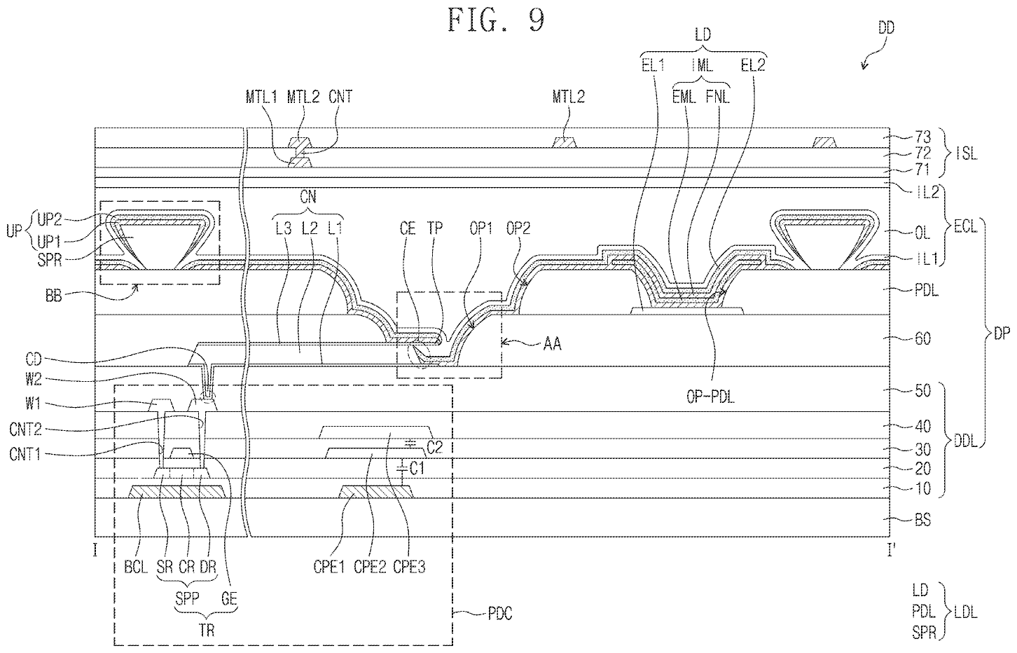

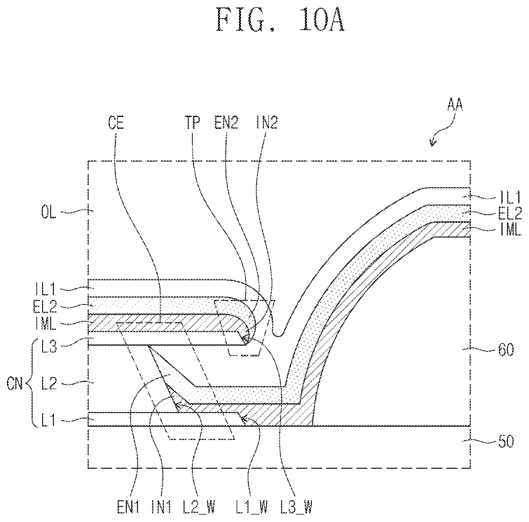

The driving connection part CD may be a portion of the connection line CN, which is connected to the pixel driver PDC. In an embodiment, the driving connection part CD may be connected to an electrode of the transistor of the pixel driver PDC. For example, the driving connection part CD may be connected to the drain of the sixth transistor T6 illustrated in FIG. 6A or the drain of the first transistor T1 illustrated in FIG. 6B. Accordingly, the position of the driving connection part CD may correspond to the position of the transistor (see reference symbol TR in FIG. 9) physically connected to the connection line CN among the pixel drivers. The light emitting connection part CE may be a portion of the connection line CN, which is connected to the light emitting element. In an embodiment, the light emitting connection part CE may be connected to the second electrode EL2 (hereinafter, referred to as a cathode) of the light emitting element.

The light emitting part UT may include first to third connection lines CN1, CN2, and CN3. The first connection line CN1 may connect the first light emitting element LD1 and the first pixel driver PDC1, which form the first light emitting part EP1, to each other, the second connection line CN2 may connect the second light emitting element LD2 and the second pixel driver PDC2, which form the second light emitting part EP2, to each other, and the third connection line CN3 may connect the third light emitting element LD3 and the third pixel driver PDC3, which form the third light emitting part EP3, to each other.

For example, the first to third connection lines CN1, CN2, and CN3 may connect the first to third cathodes EL2_1, EL2_2, and EL2_3 to the first to third pixel drivers PDC1, PDC2, and PDC3, respectively. The first connection line CN1 may include a first driving connection part CD1 (e.g., CDla and CD1b) connected to the first pixel driver PDC1 and a first light emitting connection part CE1 (e.g., CEla and CE1b) connected to the first cathode EL2_1. The second connection line CN2 may include a second driving connection part CD2 (e.g., CD2a and CD2b) connected to the second pixel driver PDC2 and a second light emitting connection part CE2 (e.g., CE2a and CE2b) connected to the second cathode EL2_2. The third connection line CN3 may include a third driving connection part CD3 (e.g., CD3a and CD3b) connected to the third pixel driver PDC3 and a third light emitting connection part CE3 (e.g., CE3a and CE3b) connected to the third cathode EL2_3.

The first to third driving connection parts CD1, CD2, and CD3 may be aligned along the first direction DR1. As described above, the first to third driving connection parts CD1, CD2, and CD3 may correspond to positions of the connection transistors of the first to third pixel drivers PDC1, PDC2, and PDC3, respectively. In a pixel, the connection transistor may be a transistor including a connection node to which the pixel driver and the light emitting element are connected. For example, the connection transistor may correspond to the sixth transistor T6 of FIG. 6A or the first transistor T1 of FIG. 6B. According to an embodiment, regardless of the shape or size of the light emitting part and the color of light, the shape, position, and arrangement of the pixel drivers of all the pixels may be simply formed to be designed.

In an embodiment, the first to third light emitting connection parts CE1, CE2, and CE3 may be disposed at positions that do not overlap the light emitting parts EP1, EP2, and EP3 in a plan view. As will be described below, since the light emitting connection part CE (see FIG. 9) of the connection line CN may be a portion at which the light emitting element LD (see FIG. 9) is connected, and a tip part TP (see FIG. 9) is defined, the light emitting connection part CE may be provided at a position that does not overlap the light emitting opening OP-PDL. For example, the light emitting connection parts CE1, CE2, and CE3 may be disposed at positions spaced apart from the light emitting parts EP1, EP2, and EP3 in each of the cathodes EL2_1, EL2_2, and EL2_3, and the cathodes EL2_1, EL2_2, and EL2_3 may include some areas protruding from the light emitting parts EP1, EP2, and EP3 in a plan view so as to be connected to the connection lines CN1, CN2, and CN3 at the positions at which the light emitting connection parts CE1, CE2, and CE3 are disposed.

For example, the first cathode EL2_1 may include a protrusion having a shape protruding from the first light emitting part EP1 at a position that does not overlap the first light emitting part EP1 so as to be connected to the first connection line CN1 at the position at which the first light emitting connection part CE1 is disposed, and the first light emitting connection part CE1 may be disposed on the protrusion.

For example, the first driving connection part CD1, which is a position at which the first pixel driver PDC1, e.g., the first connection line CN1 is connected to the transistor TR, may be defined at a position that does not overlap the first light emitting part EP1 in a plan view. According to an embodiment, the first connection line CN1 may be disposed in the first light emitting part EP1, and thus, the first cathode EL2_1 and the first pixel driver PDC1 may be readily connected to each other.

The third driving connection part CD3, which is a position at which the third pixel driver PDC3 (e.g., the third connection line CN3) is connected to the transistor TR, may be defined at a position that does not overlap the third light emitting connection part CE3 in a plan view and may be disposed at a position that overlaps the third light emitting part EP3. According to an embodiment, since the third cathode EL2_3 and the pixel driver PDC3 are connected through the third connection line CN3, in the design of the pixel driver PDC3, restriction due to the position or shape of the third light emitting part EP3 may be reduced, and a degree of freedom of the design may be improved.

Referring again to FIG. 8A, the light emitting parts in the second row Rk+1 may be formed by the light emitting parts having the shape and arrangement that are axisymmetric with respect to the axis parallel to the first direction DR1. For example, due to the characteristics of the shape and arrangement of the first row light emitting parts UT11 and UT12, the second row light emitting parts UT21 and UT22 may be substantially formed by the light emitting parts having a shape in which the first row light emitting parts UT11 and UT12 are shifted in the first direction DR1. For example, the second row first column light emitting part UT21 may be formed by the light emitting parts having the same shape as the first row second column light emitting part UT12, and the second row second column light emitting part UT22 may be formed by the light emitting parts having the same shape as the first row light emitting part UT22.

Thus, a shape and arrangement of a connection lines CN-c disposed in the second row first column light emitting part UT21 may be the same as those of connection lines CN1b, CN2b, CN3b disposed in the first row second column light emitting part UT12. For example, a shape and arrangement of a connection lines CN-d disposed in the second row second column light emitting part UT22 may be the same as those of connection lines CNla, CN2a, CN3a disposed in the first row first column light emitting part UT11.

According to an embodiment, since the connection line is provided between the light emitting element and the pixel driver, the light emitting element may be readily connected to the pixel driver although only the shape of the cathode is changed without changing the arrangement or shape of the light emitting elements. Thus, the degree of freedom in the design for the arrangement of the pixel driver may be improved, and the surface area or resolution of the light emitting part of the display panel may readily increase.

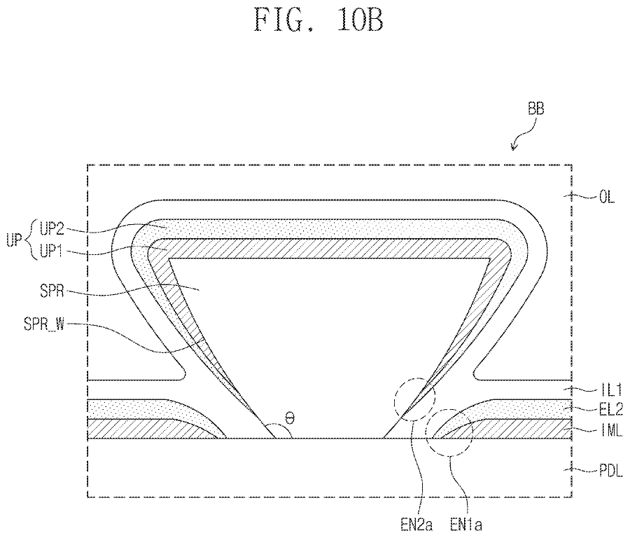

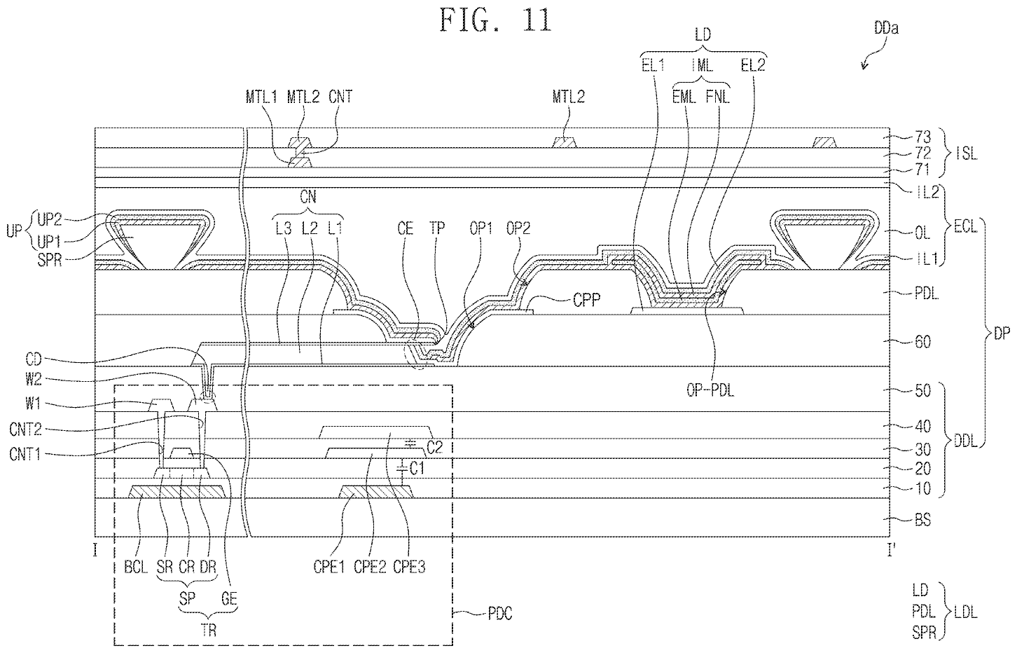

FIG. 9 is a schematic cross-sectional view of the display panel according to an embodiment. FIG. 10A is a schematic cross-sectional view illustrating a portion of an area of the display panel according to an embodiment. FIG. 10B is a schematic cross-sectional view illustrating a portion of an area of the display panel according to an embodiment. FIG. 9 is a schematic cross-sectional view illustrating a portion corresponding to a line I-I′ of FIG. 8B. FIG. 10A illustrates an enlarged schematic cross-sectional view of an area AA of FIG. 9, and FIG. 10B illustrates an enlarged schematic cross-sectional view of an area BB of FIG. 9.

Referring to FIG. 9, the display panel DP according to an embodiment may include a base layer BS, a driving element layer DDL, a light emitting element layer LDL, an encapsulation layer ECL, and a sensing layer ISL. The driving element layer DDL may include insulating layers 10, 20, 30, 40, and 50 disposed on the base layer BS, and conductive pattern layers and semiconductor pattern layers disposed between the insulating layers. The conductive pattern layers and semiconductor pattern layers may be disposed between the insulating layers to form the pixel driver PDC. FIG. 9 is a schematic cross-section view illustrating one of the areas on which one light emitting part is disposed for descriptive convenience.

The base layer BS may be a member providing a base surface on which the pixel driver PDC is disposed. The base layer BS may be a rigid substrate or a flexible substrate that is bendable, foldable, or rollable. The base layer BS may be a glass substrate, a metal substrate, or a polymer substrate. However, embodiments are not limited thereto. For example, the base layer BS may be an inorganic layer, an organic layer, or a composite layer.

The base layer BS may have a multi-layered structure. For example, the base layer SUB may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin may include a polyimide-based resin. For example, the polymer resin may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the description, the “˜˜-based” resin means as including a functional group of “˜˜”.

Each of the insulating layers, the conductive layers, and the semiconductor layers disposed on the base layer BS may be formed by a coating process or a deposition process. Thereafter, the insulating layer, the semiconductor layer, and the conductive layer may be selectively patterned through photolithography processes to define a hole in the insulating layer or may form a semiconductor pattern layer, a conductive pattern layer, and a signal line.

The driving element layer DDL may include first to fifth insulating layers 10, 20, 30, 40, and 50, which are sequentially laminated/stacked on the base layer BS, and a pixel driver PDC. FIG. 9 illustrates one transistor TR and two capacitors C1 and C2 of the pixel driver PDC. The transistor TR may correspond to a transistor connected to the light emitting element LD through the connection line CN, e.g., the connection transistor connected to the node (e.g., the fourth node N4 in FIG. 6A or the second node N2 in FIG. 6B) corresponding to the cathode of the light emitting element LD, and may correspond to the sixth transistor T6 of FIG. 6A or the first transistor T1 of FIG. 6B. For example, other transistors of the pixel driver PDC may have the same structure as the transistor TR (hereinafter, referred to as the connection transistor) illustrated in FIG. 9. However, this is an example, and other transistors of the pixel driver PDC may have structures different from those of the connection transistor TR, and embodiments are not limited thereto.

A first insulating layer 10 may be disposed on the base layer BS. The first insulating layer 10 may include an inorganic layer and/or an organic layer and have a single-layered structure or a multilayered structure. The first insulating layer 10 may include at least one of aluminum oxide, titanium oxide, silicon oxide, silicon nitride, silicon oxynitride, zirconium oxide, or hafnium oxide. In an embodiment, the first insulating layer 10 may be a single-layered silicon oxide layer. The insulating layers to be described below may be inorganic layers and/or organic layers and may have a single-layer structure or a multi-layer structure. The inorganic layer may include at least one of the above-described materials, but embodiments are not limited thereto.

The first insulating layer 10 may cover a lower conductive layer BCL. For example, the display panel may further include the lower conductive layer BCL disposed to overlap the connection transistor TR. The lower conductive layer BCL may block an electric potential due to a polarization phenomenon of the base layer BS from affecting the connection transistor TR. For example, the lower conductive layer BCL may block light incident from a lower side to the connection transistor TR. In another example, at least one of an inorganic barrier layer and a buffer layer may be further disposed between the lower conductive layer BCL and the base layer BS.

The lower conductive layer BCL may include a reflective metal. For example, the lower conductive layer BCL may include titanium (Ti), molybdenum (Mo), an alloy containing molybdenum, aluminum (Al), an alloy containing aluminum, aluminum nitride (AlN), tungsten (W), tungsten nitride (WN), and copper (Cu).

In an embodiment, the lower conductive layer BCL may be connected to a source of the transistor TR through a source electrode pattern layer W1. For example, the lower conductive layer BCL may be synchronized with the source of the transistor TR. However, this is an example, and the lower conductive layer BCL may be connected to and synchronized with the gate of the transistor TR. In another example, the lower conductive layer BCL may be connected to another electrode to independently receive a constant voltage or pulse signal. In another example, the lower conductive layer BCL may be formed in a shape that is isolated from other conductive pattern layers. The lower conductive layer BCL according to an embodiment may be formed in various shapes, but embodiments are not limited thereto.

The transistor TR may be disposed on the first insulating layer 10. The connection transistor TR may include a semiconductor pattern layer SPP and a control electrode GE. The semiconductor pattern layer SPP may be disposed on the first insulating layer 10. The semiconductor pattern layer SPP may include an oxide semiconductor. However, the oxide semiconductor may include transparent conductive oxide TCO such as indium tin oxide (ITO), indium zinc oxide (IZO), indium gallium zinc oxide (IGZO), zinc oxide (ZnO), or indium oxide (In₂O₃). However, embodiments are not limited thereto. For example, the semiconductor pattern layer SPP may include amorphous silicon, low-temperature polycrystalline silicon, or polycrystalline silicon.

The semiconductor pattern layer SPP may include a source region SR, a drain region DR, and a channel region CR, which are classified according to a degree of conductivity. The channel region CR may be a portion overlapping the gate electrode GE in a plan view. The source region SR and the drain region DR may be spaced apart with the channel region CR therebetween. In case that the semiconductor pattern layer SPP is the oxide semiconductor, each of the source region SR and the drain region DR may be a reduced area. Thus, each of the source region SR and the drain region DR may have a relatively high reduction metal content as compared to the channel region CR. In another example, in case that the semiconductor pattern layer SPP is made of polycrystalline silicon, each of the source region SR and the drain region DR may be an area doped with dopants at a high concentration.

The source region SR and the drain region DR may have conductivity relatively higher than that of the channel region CR. The source region SR may correspond to a source electrode of the connection transistor TR, and the drain region DR may correspond to a drain electrode of the connection transistor TR. As illustrated in FIG. 9, separate source electrode pattern layers W1 and drain electrode pattern layers W2 respectively connected to the source region SR and the drain region DR may be further formed. For example, each of the separate source electrode pattern layer W1 and drain electrode pattern layer W2 may be integral with one of the lines of the pixel driver (see FIGS. 6A and 6B), but embodiments are not limited thereto.

The second insulating layer 20 may overlap the pixels in common and may cover the semiconductor pattern layer SPP. The second insulating layer 20 may be an inorganic layer and/or an organic layer and may have a single-layered structure or a multilayered structure. The first insulating layer 20 may include at least one of aluminum oxide, titanium oxide, silicon oxide, silicon nitride, silicon oxynitride, zirconium oxide, or hafnium oxide. In an embodiment, the first insulating layer 20 may include a single-layered silicon oxide layer.

The gate electrode GE may be disposed on the second insulating layer 20. The gate electrode GE may correspond to the gate of the connection transistor TR. For example, the gate electrode GE may be disposed above the semiconductor pattern layer SPP. However, this is an example, and the gate electrode GE may be disposed below the semiconductor pattern layer SPP, but embodiments are not limited thereto.

The gate electrode GE may include titanium (Ti), silver (Ag), molybdenum (Mo), aluminum (Al), aluminum nitride (AlN), tungsten (W), tungsten nitride (WN), copper (Cu), or alloys thereof, but embodiments are not limited thereto.

A third insulating layer 30 may be disposed on the gate electrode GE. The third insulating layer 30 may be an inorganic layer and/or an organic layer and have a single-layered structure or a multilayered structure. The fourth insulating layer 40 may include at least one of aluminum oxide, titanium oxide, silicon oxide, silicon nitride, silicon oxynitride, zirconium oxide, or hafnium oxide.

The first capacitor electrode CPE1 and the second capacitor electrode CPE2 among the conductive pattern layers W1, W2, CPE1, CPE2, and CPE3 may form the first capacitor C1. The first capacitor electrode CPE1 and the second capacitor electrode CPE2 may be spaced apart from each other with the first insulating layer 10 and the second insulating layer 20 therebetween.

In an embodiment, the first capacitor electrode CPE1 and the lower conductive layer BCL may have an integrated shape. For example, the second capacitor electrode CPE2 and the gate electrode GE may have an integrated shape.

A third capacitor electrode CPE3 may be disposed on the third insulating layer 30. The third capacitor electrode CPE3 may be spaced apart from the second capacitor electrode CPE2 with the third insulating layer 30 therebetween and may overlap each other in a plan view. The third capacitor electrode CPE3 and the second capacitor electrode CPE2 may form the second capacitor C2.

A fourth insulating layer 40 may be disposed on the third insulating layer 30 and/or the third capacitor electrode CPE3. The fourth insulating layer 40 may be an inorganic layer and/or an organic layer and have a single-layered structure or a multilayered structure. The fourth insulating layer 40 may include at least one of aluminum oxide, titanium oxide, silicon oxide, silicon nitride, silicon oxynitride, zirconium oxide, or hafnium oxide.

A source electrode pattern layer W1 and a drain electrode pattern layer W2 may be disposed on the fourth insulating layer 40. The source electrode pattern layer W1 may be connected to the source region SR of the connection transistor TR through the first contact hole CNT1, and the source electrode pattern layer W1 and the source region SR of the semiconductor pattern layer SPP may function as a source of the connection transistor TR. The drain electrode pattern layer W2 may be connected to the drain region DR of the connection transistor TR through the second contact hole CNT2, and the drain electrode pattern layer W2 and the drain region DR of the and the semiconductor pattern layer SPP may function as a drain of the connection transistor TR. A fifth insulating layer 50 may be disposed on the source electrode pattern layer W1 and the drain electrode pattern layer W2.

A connection line CN may be disposed on the fifth insulating layer 50. The connection line CN may electrically connect the pixel driver PDC to the light emitting element LD. For example, the connection line CN may electrically connect the connection transistor TR to the light emitting element. The connection line CN may be a connection node connecting the pixel driver PDC to the light emitting element LD. For example, the connection line CN may correspond to the fourth node N4 (see FIG. 6A) illustrated in FIG. 6A or the second node N2 (see FIG. 6B) illustrated in FIG. 6B. This is an example, and in case that the connection line CN is connected to the light emitting element LD, the connection line CN may be defined as the connection node with various elements among the elements of the pixel driver PDC according to the design of the pixel driver PDC.

A sixth insulating layer 60 may be disposed on the connection line CN. The sixth insulating layer 60 may be disposed on the fifth insulating layer 50 to cover the connection line CN. Each of the fifth insulating layer 50 and the sixth insulating layer 60 may be an organic layer. For example, each of the fifth insulating layer 50 and the sixth insulating layer 60 may include general-purpose polymers such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide polymer, an aryl ether polymer, an amide polymer, a fluorine polymer, a p-xylene polymer, a vinyl alcohol polymer, and a blend thereof.

An opening exposing at least a portion of the connection line CN may be provided/defined in the sixth insulating layer 60. The connection line CN may be electrically connected to the light emitting element LD through a portion exposed from the sixth insulating layer 60. For example, the connection line CN may electrically connect the connection transistor TR to the light emitting element LD. This will be described below. In the display panel DP according to an embodiment, the sixth insulating layer 60 may be omitted or may be provided in plural, but embodiments are not limited thereto.

A light emitting element layer LDL may be disposed on the sixth insulating layer 60. The light emitting element layer LDL may include a pixel defining layer PDL, a light emitting element LD, and a separator SPR. For the pixel defining layer PDL may be an organic layer. For example, the pixel defining layer PDL may include general-purpose polymers such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide polymer, an aryl ether polymer, an amide polymer, a fluorine polymer, a p-xylene polymer, a vinyl alcohol polymer, and a blend thereof.

In an embodiment, the pixel defining layer PDL may have a property of absorbing light and may have, for example, a black color. For example, the pixel defining layer PDL may include a black coloring agent. A black component may include a black dye and a black pigment. The black component may include carbon black, a metal such as chromium, or oxide thereof. The pixel defining layer PDL may correspond to a light blocking pattern layer having light blocking properties.

An opening OP-PDL (hereinafter, a light emitting opening) exposing at least a portion of the first electrode EL1 to be described below may be defined in the pixel defining layer PDL. The light emitting opening OP-PDL may be provided in plural that are arranged to correspond for each light emitting element. In the light emitting opening OP-PDL, all components of the light emitting element LD may be disposed to overlap each other and may be an area on which light emitted by the light emitting element LD is substantially displayed. Thus, the above-described shape of the light emitting part EP (see FIG. 7A) may substantially correspond to the shape of the light emitting opening OP-PDL in a plan view.

The light emitting element LD may include a first electrode EL1, an intermediate layer IML, and a second electrode EL2. The first electrode EL1 may be a semi-transmissive electrode, a transmissive electrode, or a reflective electrode. According to an embodiment, the first electrode EL1 may include a reflective layer made of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent/translucent electrode layer disposed on the reflective layer. The transparent or translucent electrode layer may include at least one or more selected from the group consisting of indium tin oxide (ITO), indium zinc oxide (IZO), indium gallium zinc oxide (IGZO), zinc oxide (ZnO) or indium oxide (In₂O₃), and aluminum doped zinc oxide (AZO). For example, the first electrode EL1 may include a laminated/stacked structure of ITO/Ag/ITO.

In an embodiment, the first electrode EL1 may be an anode of the light emitting element LD. For example, the first electrode EL1 may be connected to the first power line VDL (see FIG. 6A), and the first power voltage VDD (see FIG. 6A) may be applied. The first electrode EL1 may be connected to the first power line VDL on the display area DA or connected to the first power line VDL on the non-display area NDA. For example, the first power line VDL may be disposed on the non-display area NDA, and the first electrode EL1 may have a shape extending to the non-display area NDA.

In the schematic cross-sectional view of FIG. 9, the first electrode EL1 may overlap the light emitting opening OP-PDL and may not overlap the separator SPR, but the first electrode EL1 of each of the light emitting elements may have an integrated shape and have a mesh shape or a lattice shape in which openings are defined in some areas. For example, in case that the same first power voltage VDD is applied to the first electrode EL1 of each of the light emitting elements, the shape of the first electrode EL1 may be formed in various manners, but embodiments are not limited thereto.

The intermediate layer IML may be disposed between the first electrode EL1 and the second electrode EL2. The intermediate layer IML may include an emission layer EML and a functional layer FNL. The light emitting element LD may include an intermediate layer IML having various structures, but embodiments are not limited thereto. For example, the functional layer FNL may be formed as a plurality of layers or as two or more layers spaced apart from each other with the emission layer EML therebetween. In another example, in an embodiment, the functional layer FNL may be omitted.

The emission layer EML may include an organic light emitting material. For example, the emission layer EML may include an inorganic light emitting material or may be formed as a mixed layer of an organic light emitting material and an inorganic light emitting material. In an embodiment, the emission layers EML formed in each adjacent light emitting part EP may include light emitting materials displaying different colors. For example, the emission layer EML formed in each light emitting part EP may provide one of blue light, red light, and green light. However, embodiments are not limited thereto, and the emission layer EML disposed on all the light emitting parts EP may include a light emitting material displaying the same color. For example, the emission layer EML may provide blue light or white light. For example, in FIG. 9, the emission layer EML and the functional layer FNL are illustrated as an embodiment in different shapes, but embodiments are not limited thereto, and the emission layer EML and the functional layer FNL may be disposed in the same shape in a plan view.

The functional layer FNL may be disposed between the first electrode EL1 and the second electrode EL2. For example, the functional layer FNL may be disposed between the first electrode EL1 and the emission layer EML or between the second electrode EL2 and the emission layer EML. In another example, the functional layer FNL may be disposed between the first electrode EL1 and the emission layer EML and between the second electrode EL2 and the emission layer EML. In an embodiment, the emission layer EML is illustrated as being inserted into the functional layer FNL. However, this is an example, and the functional layer FNL may include a layer disposed between the emission layer EML and the first electrode EL1 and/or a layer disposed between the emission layer EML and the second electrode EL2 and may be formed in plural, but embodiments are not limited thereto.

The functional layer FNL may control movement of charges between the first electrode EL1 and the second electrode EL2. The functional layer FNL may include a hole injection/transport material and/or an electron injection/transport material. The functional layer FNL may include at least one of an electron blocking layer, a hole transporting layer, a hole injection layer, a hole blocking layer, an electron transporting layer, an electron injection layer, or a charge generating layer.

The second electrode EL2 may be disposed on the intermediate layer IML. As described above, the second electrode EL2 may be connected to the connection line CN and electrically connected to the pixel driver PDC. For example, the second electrode EL2 may be electrically connected to the connection transistor TR through the connection line CN.

As described above, the connection line CN may include a driving connection part CD and a light emitting connection part CE. The driving connection part CD may be a portion of the connection line CN, which is connected to the pixel driver PDC, and a portion that is substantially connected to the connection transistor TR. In an embodiment, the driving connection part CD may pass through the fifth insulating layer 50 and be electrically connected to the drain region DR of the semiconductor pattern layer SPP through the drain electrode pattern layer W2. The light emitting connection part CE may be a portion of the connection line CN, which is connected to the light emitting element LD. The light emitting connection part CE may be defined on an area exposed from the sixth insulating layer 60 and may be a portion to which the second electrode EL2 is connected. For example, a tip part TP may be defined/formed in the light emitting connection part CE.

The light emitting connection part CE of the connection line CN will be described with reference to FIGS. 9 and 10A. As illustrated in FIGS. 9 and 10A, the connection line CN may have a three-layer structure. For example, the connection line CN may include a first layer L1, a second layer L2, and a third layer L3, which are sequentially laminated/stacked along the third direction DR3. The second layer L2 may include a material different from that of the first layer L1. For example, the second layer L2 may include a material different from that of the third layer L3. The second layer L2 may have a relatively thick thickness as compared to the first layer L1. For example, the second layer L2 may have a relatively thick thickness as compared to the third layer L3. The second layer L2 may include a highly conductive material. In an embodiment, the second layer L2 may include aluminum (Al).

For example, the first layer L1 may include a material having a lower etch rate than the second layer L2. For example, the first layer L1 and the second layer L2 may be made of materials having a high etching selectivity with respect to each other. In an embodiment, the first layer L1 may include titanium (Ti), and the second layer L2 may include aluminum (Al). For example, a side surface L1_W of the first layer L1 may be defined/protruded outside a side surface L2_W of the second layer L2. For example, the light emitting connection part CE of the connection line CN may have a shape in which the side surface L1_W of the first layer L1 protrudes outward from the side surface L2_W of the second layer L2. For example, the light emitting connection part CE of the connection line CN may have a shape in which the side surface L2_W of the second layer L2 is recessed inward from the side surface L1_W of the first layer L1.

For example, the third layer L3 may include a material having a lower etch rate than the second layer L2. For example, the third layer L3 and the second layer L2 may be made of materials having a high etching selectivity with respect to each other. In an embodiment, the third layer L3 may include titanium (Ti), and the second layer L2 may include aluminum (Al). For example, a side surface L3_W of the third layer L3 may be defined/protruded outside the side surface L2_W of the second layer L2. For example, the light emitting connection part CE of the connection line CN may have a shape in which the side surface L3_W of the third layer L3 protrudes outward from the side surface L2_W of the second layer L2. For example, the light emitting connection part CE of the connection line CN may have an undercut shape or an overhang structure, and the tip part TP of the light emitting connection part CE may be defined by a protruding portion of the third layer L3 as compared to the second layer L2.

The sixth insulating layer 60 and the pixel defining layer PDL may expose at least a portion of the tip part TP and at least a portion of the second side surface L2_W. For example, the first opening OP1 exposing one side of the connection line CN may be defined in the sixth insulating layer 60, and the second opening OP2 overlapping the first opening OP1 may be defined in the pixel defining layer PDL. A planar area/size of the second opening OP2 may be larger than that of the first opening OP1. However, embodiments are not limited thereto, and in case that at least a portion of the tip part TP and at least a portion of the second side surface L2_W are exposed, the planar area/size of the second opening OP2 may be less than or equal to that of the first opening OP1.

An intermediate layer IML may be disposed on the pixel defining layer PDL. The intermediate layer IML may also be disposed on a portion of the sixth insulating layer 60 exposed by the second opening OP2 of the pixel defining layer PDL. For example, the intermediate layer IML may also be disposed on a portion of the connection line CN exposed by the first opening OP1 of the sixth insulating layer 60. As illustrated in FIG. 10A, the intermediate layer IML may include an end portion IN1 disposed along a top surface (or upper surface) of the fifth insulating layer 50 and another end portion IN2 disposed along a top surface (or upper surface) of the tip part TP. For example, when viewed in cross-section, the intermediate layer IML may have a shape in which the connection is partially disconnected with respect to the tip part TP in the area on which the light emitting connection part CE is defined. However, when viewed in a plan view, the intermediate layer IML may have an integrated shape connected as a whole within an area (see FIG. 8A) defined as a closed line by the separator.

A second electrode EL2 may be disposed on the intermediate layer IML. The second electrode EL2 may also be disposed on a portion of the sixth insulating layer 60 exposed by the second opening OP2 of the pixel defining layer PDL. For example, the second electrode EL2 may be disposed on a portion of the connection line CN exposed by the first opening OP1 of the sixth insulating layer 60. As illustrated in FIG. 10A, the second electrode EL2 may include an end portion EN1 of the second electrode EL2, which is disposed along the top surface (or upper surface) of the fifth insulating layer 50, and another end portion EN2 disposed along the top surface (or upper surface) of the tip part TP. For example, when viewed in cross-section, the second electrode EL2 may have a shape in which the connection is partially disconnected with respect to the tip part TP in the area on which the light emitting connection part CE is defined. However, in a plan view, the second electrode EL2 may have an integrated shape connected as a whole within an area defined as a closed curve by the separator.

The end portion EN1 of the second electrode EL2 may be disposed along the side surface of the second layer L2 so as to be in contact with the side surface L2_W of the second layer L2. For example, the second electrode EL2 may be disposed to be in contact with the side surface L2_W of the second layer L2 exposed from the intermediate layer IML by the tip part TP through a difference in deposition angle between the second electrode EL2 and the intermediate layer IML. For example, the second electrode EL2 may be connected to the connection line CN without a separate patterning process for the intermediate layer IML, and thus the light emitting element LD may be electrically connected to the pixel driver PDC through the connection line CN.

In an embodiment, the another end portion IN2 of the intermediate layer IML and the another end portion EN2 of the second electrode EL2 are illustrated as covering the side surface L3_W of the third layer L3, but this is an example, and at least a portion of the side surface L3_W of the third layer L3 may be exposed from the another end portion IN2 of the intermediate layer IML and/or the another end portion EN2 of the second electrode EL2.

As described above, the display panel DP may include the separator SPR. The separator SPR may be disposed on the pixel defining layer PDL. In an embodiment, the second electrode EL2 and the intermediate layer IML may be formed to be commonly deposited on the pixels through an open mask. For example, the second electrode EL2 and the intermediate layer IML may be divided by the separator SPR. As described above, the separator SPR may have a closed line shape for each light emitting part, and thus the second electrode EL2 and the intermediate layer IML may have a divided shape for each light emitting part. For example, the second electrode EL2 and the intermediate layer IML may be electrically independent for each adjacent pixel.

The separator SPR will be described in more detail with reference to FIGS. 9 and 10B. As illustrated in FIG. 10B, the separator SPR may have a reverse tapered shape. For example, an angle θ (hereinafter, referred to as a taper angle) defined by the side surface SPR_W of the separator SPR with respect to the top surface (or upper surface) of the pixel defining layer PDL may be an obtuse angle. However, this is an example, and in case that the separator SPR electrically disconnects the second electrode EL2 for each pixel, the taper angle θ may be set in various manners. For example, the separator SPR may have the same structure as the tip part TP, but embodiments are not limited thereto.

In an embodiment, the separator SPR may include an insulating material and may include an organic insulating material. The separator SPR may include an inorganic insulating material, formed as a multi-layer structure of an organic insulating material and an inorganic insulating material, and include a conductive material according to an embodiment. For example, as long as the second electrode EL2 is electrically disconnected for each pixel, the type of the material of the separator SPR is not limited thereto.

A dummy layer UP may be disposed on the separator SPR. The dummy layer UP may include a first dummy layer UP1 disposed on the separator SPR and a second dummy layer UP2 disposed on the first dummy layer UP1. The first dummy layer UP1 may be formed by the same process as the intermediate layer IML and may include the same material. The second dummy layer UP2 may be formed by the same process as the second electrode EL2 and may include the same material. For example, the first dummy layer UP1 and the second dummy layer UP2 may be formed simultaneously during the formation of the intermediate layer IML and the second electrode EL2. In another embodiment, the display panel DP may not include the dummy layer UP.

As illustrated in FIG. 10B, in an embodiment, the second electrode EL2 may include a first end portion EN1a, and the second dummy layer UP2 may include a second end portion EN2a. The first end portion EN1a may be spaced apart from the separator SPR and disposed on the pixel defining layer PDL, and the second end portion EN2a may be separated from the first end portion EN1a and disposed on the side surface SPR_W of the separator SPR. However, in FIG. 10B, the first end portion EN1a is illustrated to be spaced a certain distance from the side surface SPR_W of the separator SPR, but embodiments are not limited thereto. For example, as long as the first end portion EN1 is electrically disconnected from the second end portion EN2a, the first end portion EN1a may also be in contact with the side surface SPR_W of the separator SPR. For example, although the first end portion EN1a and the second end portion EN2a are connected without being distinguished from each other, in case that a thickness of the portion disposed along the side surface SPR_W of the separator SPR is thin so that electrical resistance is high, in case that the second electrode EL2 between the adjacent pixels is electrically disconnected, it is assumed that the second electrode EL2 is divided by the separator SPR.

According to an embodiment, although there is no separate patterning process for the second electrode EL2 or the intermediate layer IML, the second electrode EL2 or the intermediate layer IML may not be formed on the side surface SPR_W of the separator SPR or may be formed to be thin, and thus, the second electrode EL2 or the intermediate layer IML may be divided for each pixel. For example, in case that the second electrode EL2 or the intermediate layer IML are electrically disconnected between the adjacent pixels, the shape of the separator SPR may be modified in various manners, but embodiments are not limited thereto.

Referring again to FIG. 9, the encapsulation layer ECL may be disposed on the light emitting element layer LDL. The encapsulation layer ECL may cover the light emitting element LD to cover the separator SPR. The encapsulation layer ECL may include a first inorganic layer IL1, an organic layer OL, and a second inorganic layer IL2, which are sequentially laminated/stacked. However, embodiments are not limited thereto. For example, the encapsulation layer ECL may further include inorganic layers and organic layers. For example, the encapsulation layer ECL may be a glass substrate.

The first and second inorganic layers IL1 and IL2 may protect the light emitting element LD from moisture and oxygen outside the display panel DP, and the organic layer OL may protect the light emitting element LD from foreign substances such as particles remaining in the process of forming the first inorganic layer IL1. Each of the first and second inorganic layers IL1 and IL2 may include a silicon nitride layer, a silicon oxynitride layer, a silicon oxide layer, a titanium oxide layer, an aluminum oxide layer, or the like. The organic layer OL may include an acryl-based organic layer, and the type of material is not limited thereto.

The sensing layer ISL may sense an external input. In an embodiment, the sensing layer ISL may be disposed on the encapsulation layer ECL by a continuous process. For example, the sensing layer ISL may be disposed (e.g., directly disposed) on the encapsulation layer ECL. The direct disposition may mean that no other components are disposed between the sensing layer ISL and the encapsulation layer ECL. For example, a separate adhesive member may not be disposed between the sensing layer ISL and the encapsulation layer ECL. However, this is an example, and in the display panel DP according to an embodiment, the sensing layer ISL may be separately formed and coupled to the display panel DP by an adhesive member, but embodiments are not limited thereto.

The sensing layer ISL may include conductive layers and insulating layers. The conductive layers may include a first sensing conductive layer MTL1 and a second sensing conductive layer MTL2, and the insulating layers may include first to third sensing insulating layers 71, 72, and 73. However, this is an example, and the number of conductive layers and insulating layers is not limited thereto.

The first to third sensing insulating layers 71, 72, and 73 may have a single-layer structure or a multi-layer structure in which layers are laminated/stacked in the third direction DR3. Each of the first to third sensing insulating layers 71, 72, and 73 may include an inorganic layer. The inorganic layer may include at least one of aluminum oxide, titanium oxide, silicon oxide, silicon nitride, silicon oxynitride, zirconium oxide, or hafnium oxide. Each of the first to third sensing insulating layers 71, 72, and 73 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The first sensing conductive layer MTL1 may be disposed between the first sensing insulating layer 71 and the second sensing insulating layer 72, and the second sensing conductive layer MTL2 may be disposed between the second sensing insulating layer 72 and the third sensing insulating layer 73. A portion of the second sensing conductive layer MTL2 may be connected to the first sensing conductive layer MTL1 through a contact hole CNT defined in the second sensing insulating layer 72. Each of the first sensing conductive layer MTL1 and the second sensing conductive layer MTL2 may have a single-layer structure or a multi-layer structure laminated/stacked along the third direction DR3.

The single-layered sensing conductive layer may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), or indium zinc tin oxide (IZTO). In another example, the transparent conductive layer may include a conductive polymer such as poly(3,4-ethylenedioxythiophene) (PEDOT), a metal nanowire, graphene, and the like.

The multi-layered sensing conductive layer may include metal layers. The metal layers may have, for example, a three-layered structure of titanium (Ti)/aluminum (Al)/titanium (Ti). In another example, the conductive layer having the multilayered structure may include at least one metal layer and at least one transparent conductive layer.

The first sensing conductive layer MTL1 and the second sensing conductive layer MTL2 may form a sensor that senses an external input in the sensing layer ISL. The sensor may be driven by a capacitive method and may be driven by one of a mutual-cap method and a self-capacitive method. However, this is an example, and the sensor may be driven by a resistive film method, an ultrasonic method, or an infrared method in addition to the capacitive method, but embodiments are not limited thereto.

Each of the first sensing conductive layer MTL1 and the second sensing conductive layer MTL2 may include a transparent conductive oxide or may have a metal mesh shape made of an opaque conductive material. The first sensing conductive layer MTL1 and the second sensing conductive layer MTL2 may have various materials and various shapes as long as visibility of an image displayed by the display panel DP is not deteriorated, but embodiments are not limited thereto.

FIG. 11 is a schematic cross-sectional view of the display panel according to an embodiment. For descriptive convenience, FIG. 11 is a schematic cross-sectional view illustrating an area corresponding to FIG. 9. Hereinafter, the same reference numeral may be given to components that are the same as those of FIGS. 1 to 10B, and their descriptions will be omitted for descriptive convenience.

As compared to the display device DDa illustrated in FIG. 11, the display device DDa illustrated in FIG. 9 may further include a capping pattern layer CPP. The capping pattern layer CPP may be disposed on the sixth insulating layer 60. For example, the capping pattern layer CPP may be disposed on a portion of the connection line CN exposed by the first opening OP1 of the sixth insulating layer 60. The capping pattern layer CPP may be disposed to overlap the connection line CN, and may be disposed to overlap the light emitting connection part CE and/or the tip part TP.

As illustrated in FIG. 11, when viewed in cross-section, the capping pattern layer CPP may have a shape which is partially disconnected with respect to the tip part TP on the area where the light emitting connection part CE is defined. However, in a plan view, the capping pattern layer CPP may have an integrated shape connected as a whole within an area defined as a closed line by the separator (see FIG. 4). An end portion of the partially disconnected capping pattern layer CPP may be in contact with the side surface of the second connection line layer L2, and another end portion of the capping pattern layer CPP may be disposed on an upper portion of the third layer L3 of the connection line to cover the tip part TP.

The capping pattern layer CPP may include a conductive material. Thus, the second electrode EL2 may be electrically connected to the connection line CN through the capping pattern layer CPP. For example, the capping pattern layer CPP may be in contact with the side surface of the second layer L2 of the connection line CN, and the second electrode EL2 may be in electrically contact with the capping pattern layer CPP to electrically connect all of the connection lines. The capping pattern layer CPP may be disposed relatively outside the second layer L2 of the connection line CN, and the second electrode EL2 may be electrically connected to the second layer L2 by being only connected to the capping pattern layer CPP instead of the side surface of the second layer L2, and thus, the connection between the connection line CN and the second electrode E2 may be more readily performed.

For example, the capping pattern layer CPP may include a material having a relatively low reactivity as compared to the second connection line layer L2. For example, the capping pattern layer CPP may include copper (Cu), silver (Ag), a transparent conductive oxide, or the like. As the side surface of the second connection line layer L2 is protected by the capping pattern layer CPP having the relatively low reactivity, oxidation of a material contained in the second layer L2 may be prevented. For example, during an etching process of patterning the first electrode EL1, a phenomenon in which a silver (Ag) component provided in the layer of the first electrode EL1 is reduced to remain as particles causing defects may be prevented.

In an embodiment, the capping pattern layer CPP and the first electrode EL1 may be formed by the same process and may include the same material. However, this is an example, and the capping pattern layer CPP may be formed by a process different from that of the first electrode EL1 or may include a different material, but embodiments are not limited thereto.

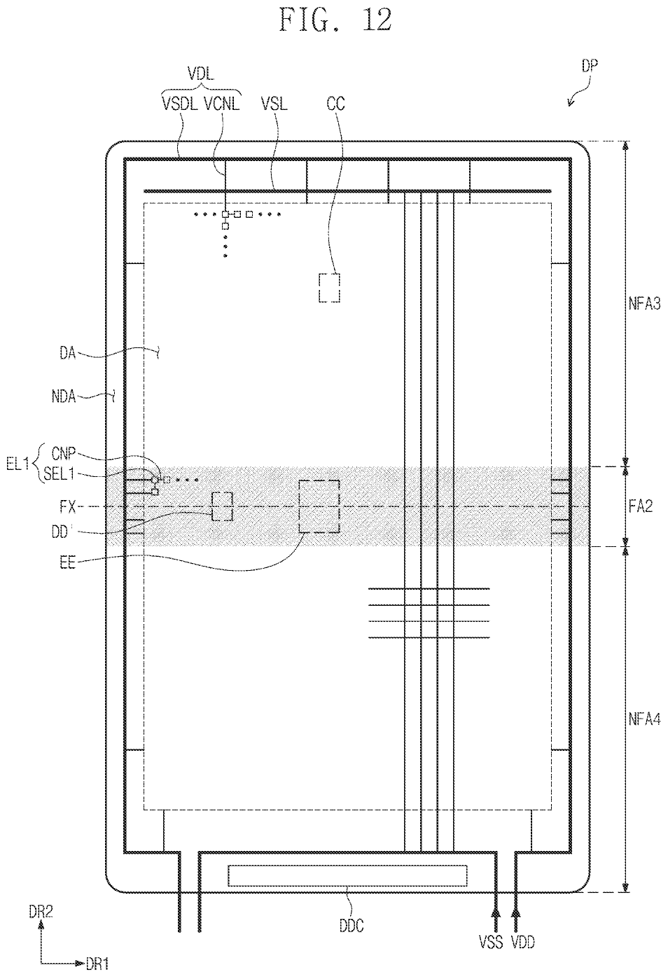

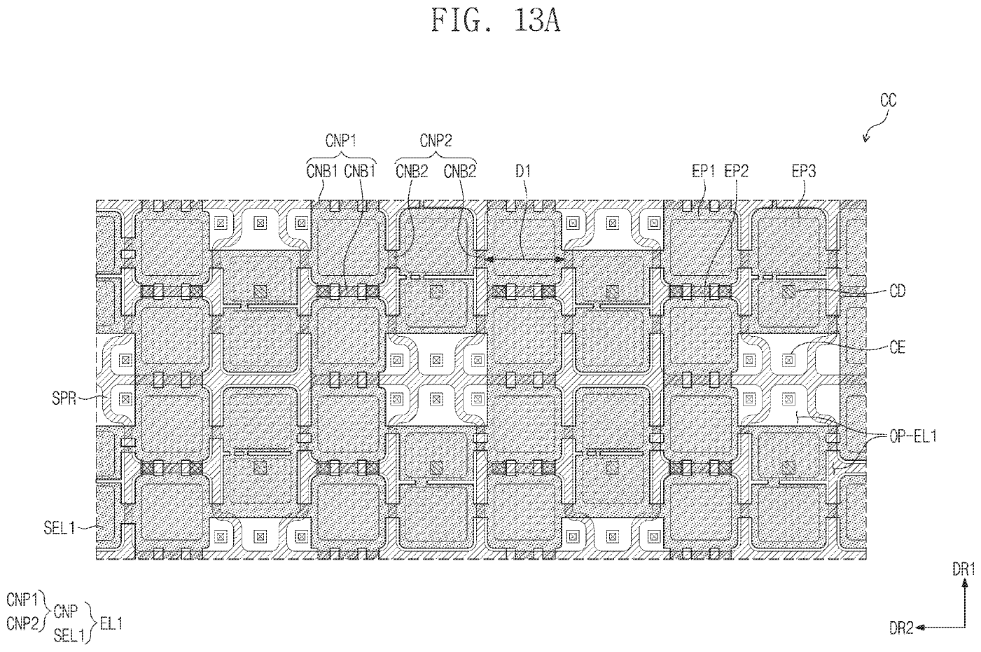

FIG. 12 is a schematic plan view of a display panel according to an embodiment. FIG. 13A is an enlarged schematic view illustrating an area CC of FIG. 12. FIG. 13B is an enlarged schematic view illustrating an area DD′ of FIG. 12. FIG. 13C is an enlarged schematic view illustrating an area EE of FIG. 12. The display panel DP may be divided into a second folding area FA2 and at least one non-folding area NFA1 and NFA2. The second folding area FA2 may be an area that is folded with respect to the folding axis FX to substantially define a curvature. The second folding area FA2 may be defined as an area that is folded along the folding axis FX and extends in the first direction DR1. The non-folding areas NFA3 and NFA4 may include a third non-folding area NFA3 and a fourth non-folding area NFA4. Hereinafter, for convenience of description, the second folding area FA2 will be referred to as a folding area, and the third and fourth non-folding areas NFA3 and NFA4 will be referred to as non-folding areas. Hereinafter, embodiments will be described with reference to FIGS. 12 to 13B.

Referring to FIGS. 12 and 13A, a first electrode EL1 may be commonly provided to light emitting parts EP1, EP2, and EP3. The first electrode EL1 may be formed as an integrated single layer on the display area DA as a whole, and thus, the first electrode EL1 may be disposed to overlap a separator SPR. The first electrode EL1 may include first sub electrodes SEL1 corresponding to the light emitting parts EP1, EP2, and EP3 (or light emitting layers EML, see FIG. 9) and a connection pattern layer CNP electrically connecting the first sub electrodes SEL1 to each other. Since the first sub electrodes SEL1 correspond to the light emitting parts EP1, EP2, and EP3, the first sub electrodes SEL1 may be divided by the separator SPR. The connection pattern layer CNP may be a pattern layer electrically connecting the first sub electrodes SEL1 to each other and may be disposed to overlap the separator SPR. In FIG. 12, the first sub electrodes SEL1 and the connection pattern layer CNP are illustrated.

In an embodiment, the connection pattern layer CNP may include a first connection pattern layer CNP1 electrically connecting the first sub electrodes SEL1 to each other in the first direction DR1 and a second connection pattern layer CNP2 electrically connecting the first sub electrodes SEL1 to each other in the second direction DR2. The first sub electrodes SEL1 may be arranged in the first and second directions DR1 and DR2. The first connection pattern layer CNP1 may electrically connect the first sub electrodes SEL1 arranged in the first direction DR1 to each other, and the second connection pattern layer CNP2 may electrically connect the first sub electrodes SEL1 arranged in the second direction DR2 to each other. Hereinafter, for descriptive convenience, the connection pattern layer CNP will be expressed as a connection pattern layer CNP in the non-folding areas NFA3 and NFA4 and a connection pattern layer CNPa in the folding area FA2.

According to an embodiment, a voltage line may be disposed outside the first electrode EL1. For example, a first power line VDL may be disposed outside the first electrode EL1 to overlap the display area DA and the non-display area NDA. The first power line VDL may receive a first power voltage VDD from a power supply PWS (refer to FIG. 5). The second power line VSL may be disposed to overlap the display area DA and the non-display area NDA. The second power line VSL may be formed in a mesh shape on the display area DA. The second power line VSL may receive a second power voltage VSS from the power supply PWS.

The first power line VDL disposed outside the first electrode EL1 may apply the first power voltage VDD supplied from the power supply PWS to the first electrode EL1. For example, the first power line VDL may include a first reference line VSDL and connection lines VCNL connected to the first reference line VSDL. The first reference line VSDL disposed on the non-display area NDA may apply the first power voltage VDD to the first electrode EL1 through connection lines VCNL connected to the first reference line VSDL. The connection lines VCNL may overlap the display area DA and the non-display area NDA. The first power line VDL may apply the first power voltage VDD to the outermost first sub electrodes SEL1 among the first sub electrodes SEL1. The first sub electrodes SEL1 disposed inside may receive the first power voltage VDD applied to the outermost first sub electrodes SEL1 through the connection pattern layer CNP.

FIG. 13A is an enlarged schematic view illustrating a portion CC of the display area DA of the non-folding area NFA3 and NFA4.

Referring to FIG. 13A, the first connection pattern layer CNP1 may include first connection parts CNB1 electrically connecting the first sub electrodes SEL1, which are adjacent to each other in the first direction DR1, and second connection parts CNB2 electrically connecting the first sub electrodes SEL1, which are adjacent to each other in the second direction DR2. The first connection parts CNB1 may have different shapes and sizes. Each of the first connection parts CNB1 may be formed as a plurality of lines spaced apart from each other in the second direction DR2. Each of the first connection parts CNB1 is illustrated as including two or three lines, but embodiments are not limited thereto. For example, each of the first connection parts CNB1 may be formed as a single line or include four or more lines. The second connection parts CNB2 may have different shapes and different sizes. Each of the second connection parts CNB2 may include one or two lines. However, embodiments are not limited thereto, and the second connection parts CNB2 may be formed as a single line or include three or more lines. According to an embodiment, a density of the first connection pattern layer CNP1 and a density of the second connection pattern layer CNP2 may be different from each other. For example, the density of the first connection pattern layer CNP1 may be greater than that of the second connection pattern layer CNP2.

According to an embodiment, the connection pattern layer CNP may not overlap the first connection portion CE (or light emitting connection part) in a plan view. As illustrated in the drawings, in the first connection portions CE, six first connection portions CE may be disposed in one group, and the connection pattern layer CNP may be spaced apart from the first connection portions CE formed in six groups in a plan view. The first connection parts CNB1 electrically connecting the third light emitting part EP3 to the corresponding first sub electrodes SEL1 in the first direction DR1 may be disposed to be spaced apart from the first connection portions CE in the first direction DR1. The first connection parts CNB1 electrically connecting the first and second light emitting parts EP1 and EP2 to the corresponding first sub electrodes SEL1 in the first direction DR1 may be disposed to be spaced apart from the first connection portions CE in the second direction DR2. The second connection parts CNB2 may be disposed to be spaced apart from the first connection portions CE in the first direction DR1.

Electrode openings OP-EL1 may be defined in the first electrode EL1, and the electrode openings OP-EL1 may pass through the first electrode EL1. The electrode openings OP-EL1 may be disposed at a position that does not overlap the light emitting parts EP and may generally be defined at a position overlapping the separator SPR. The electrode openings OP-EL1 may facilitate discharge of a gas generated from an organic layer disposed below the first electrode EL1, for example, the sixth insulating layer 60 (see FIG. 9). Thus, the gas from the organic layer disposed below the light emitting device may be sufficiently discharged during a process of manufacturing the display panel, and a rate of deterioration of the light emitting device may be reduced due to the reduced gas discharged from the organic layer after the manufacturing.

FIG. 13B is an enlarged schematic view illustrating a portion DD′ of the display area of the folding area FA2.

Referring to FIGS. 13A and 13B, a density of the connection pattern layer CNPa illustrated in FIG. 13B may be different from that of the connection pattern layer CNP illustrated in FIG. 13A. For example, the density of the connection pattern layers CNPa in the folding area FA2 may be different from that of the connection pattern layers CNP in the non-folding areas NFA3 and NFA4. According to an embodiment, the density of the connection pattern layers CNPa in the folding area FA2 may be less than that of the connection pattern layers CNP in the non-folding areas NFA3 and NFA4. In the second connection pattern layers CNP2a illustrated in FIG. 13B, a portion of the second connection pattern layers CNP2 illustrated in FIG. 13A disposed in an area overlapping the folding axis (or virtual axis) FX is omitted. For example, in the second connection pattern layers CNP2a illustrated in FIG. 13B, a portion of the second connection pattern layers CNP2 illustrated in FIG. 13A disposed in an area overlapping a first axis X1 and a second axis X2 parallel to the folding axis FX is omitted. For example, a density of the second connection pattern layers CNP2a overlapping the folding area FA2 may be greater than that of the second connection pattern layers CNP2 overlapping the non-folding areas NFA3 and NFA4 illustrated in FIG. 13A. For example, the density of the first connection pattern layer CNP1 and the density of the second connection pattern layer CNP2a in the folding area FA2 may be different from each other. For example, the density of the first connection pattern layer CNP1 may be greater than that of the second connection pattern layer CNP2a.

For example, the number of second connection parts CNB2a illustrated in FIG. 13B may be different from the number of second connection parts CNB2 illustrated in FIG. 13A. For example, based on the same area, the number of second connection parts CNB2a in the folding area FA2 may be less than the number of second connection parts CNB2 in the non-folding areas NFA3 and NFA4. For example, in case that a distance between two second connection parts CNB2a adjacent to each other in the first direction DR1 among the second connection parts CNB2a in the folding area FA2 is defined as a first distance D1, and a distance between two second connection parts CNB2 adjacent to each other in the first direction DR1 among the second connection parts CNB2 in the non-folding areas NFA3 and NFA4 is defined as a second distance D2, the first distance D1 and the second distance D2 may be different from each other. Since the second connection parts CNB2a in the folding area FA2 are not formed on an area overlapping the folding axis FX, the first axis X1, and the second axis X2, the second distance D2 may be greater than the first distance D1.

Referring to FIGS. 12, 13A, and 13B, in the display panel DP according to an embodiment, the density of the connection pattern layers CNPa in the folding area FA2 may be less than that of the connection pattern layers CNP in the non-folding areas NFA3 and NFA4. During the folding operation, stress may occur in the connection pattern layer CNP formed in the first electrode EL1, and stress may be concentrated in the connection pattern layer CNPa disposed in the folding area FA2. The density of the connection pattern layers CNPa in the folding area FA2 may be less than the density of the connection pattern layers CNP in the non-folding areas NFA3 and NFA4, and thus, compression and tensile stresses applied to the connection pattern layers CNPa during the folding operation may be dispersed to prevent damage due to the folding of the connection pattern layer CNP from occurring.

As described with reference to FIG. 13B, to prevent the damage to the connection pattern layer CNP due to the folding, the second connection parts CNB2a connecting the first sub electrodes SEL1 to each other may not be partially formed in the folding area FA2. Thus, some of the first sub electrodes SEL1 disposed in the folding area FA2 may not receive the first power voltage VDD, or as a current path of the first sub electrodes SEL1 disposed in the folding area FA2 becomes longer, a voltage level of the first power voltage VDD may be changed due to a voltage drop (or IR drop) phenomenon.

Referring again to FIG. 12, the density of the connection lines VCNL overlapping the folding area FA2 and the density of the connection lines VCNL overlapping the non-folding areas NFA3 and NFA4 may be different from each other. To prevent a limitation in which the first sub electrodes SEL1 disposed in the folding area FA2 do not receive the first power voltage VDD from occurring, the density of the connection lines VCNL in the folding area FA2 may be greater than that of the connection lines VCNL in the non-folding area NFA3 and NFA4. For example, each of the first sub electrodes SEL1 overlapping the folding area FA2 and disposed at the outermost side may be connected to the connection lines VCNL to directly receive the first power voltage VDD. Each of the first sub electrodes SEL1 overlapping the folding area FA2 and disposed at the outermost side may be connected to the connection lines VCNL to receive the first power voltage VDD, and thereby all of the first sub electrodes SEL1 overlapping the folding area FA2 disposed in the first direction DR1 may receive the first power voltage VDD. Thus, the second connection parts CNB2a connecting the first sub electrodes SEL1 to each other may not be partially formed in the folding area FA2, and thus, the voltage drop phenomenon occurring as the current path of the first sub-electrodes SEL1 becomes longer may be prevented, and display quality deterioration of the display device DD (see FIG. 1) may be prevented.

FIG. 13C is an enlarged schematic view illustrating the folding area FA2 of FIG. 12. FIG. 13C is illustrated to emphasize characteristics of the connection pattern layer CNP as compared to FIG. 13B.

Referring to FIG. 13C, the first sub electrodes SEL1 arranged in the first and second directions DR1 and DR2, the first connection pattern layers CNP1 electrically connecting the first sub electrode SEL1 to each other in the first direction DR1, and the second connection pattern layers CNP2a electrically connecting the first sub electrodes SEL1 to each other in the second direction DR2 may be disposed in the folding area FA2. The first connection pattern layers CNP1 may electrically connect all the first sub electrodes SEL1, which are adjacent to each other in the first direction DR1, to each other. According to an embodiment, the second connection pattern layers CNP2a may electrically connect only portions of the first sub electrodes SEL1, which are adjacent to each other in the second direction DR2, to each other.

According to an embodiment, the density of the second connection pattern layers CNP2a may gradually decrease as being closer to the folding axis FX. For example, the number of second connection parts CNB2 formed in each of the second connection pattern layers CNP2a may gradually decrease as being closer to the folding axis FX. Since the number of second connection parts CNB2 formed in each of the second connection pattern layers CNP2a gradually decreases as being closer to the folding axis FX, the density of the second connection pattern layers CNP2a based on the same area may gradually decrease as being closer to the axis FX.

According to an embodiment, a distance between the second connection parts CNB2 arranged in the first direction DR1 may gradually increase as being closer to the folding axis FX. For example, since the number of second connection parts CNB2 formed in each of the second connection pattern layers CNP2a gradually decreases as being closer to the folding axis FX, the distance between the second connection parts CNB2 adjacent to each other in the first direction DR1 may gradually decrease as being closer to the folding axis FX. Thus, the distance between the second connection parts CNB2 of the second connection pattern layers CNP2a arranged in the first direction DR1 on the area overlapping the folding axis FX among the second connection pattern layers CNP2a may be the largest.

During the folding operation, stress may occur in the second connection pattern layers CNP2a disposed in the folding area FA2. For example, since a degree of folding gradually increases as being closer to the folding axis FX, more stress may occur in the second connection pattern layers CNP2a as being closer to the folding axis FX. The density of the second connection pattern layers CNP2a formed in the display panel DP according to an embodiment may gradually decrease as being closer to the folding axis FX. As the density of the second connection pattern layers CNP2a is differentially designed, e.g., the density of the second connection pattern layers CNP2a is set to gradually decrease as being closer to the folding axis FX, the compression and tensile stresses acting on the second connection pattern layers CNP2a may be efficiently dispersed to prevent damage due to the folding of the second connection pattern layers CNP2a.

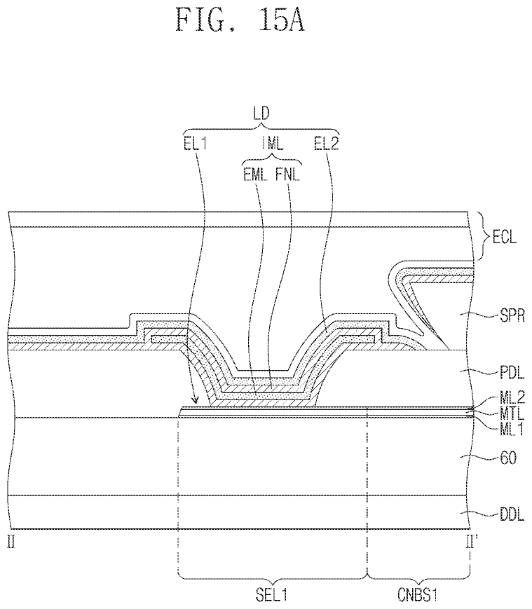

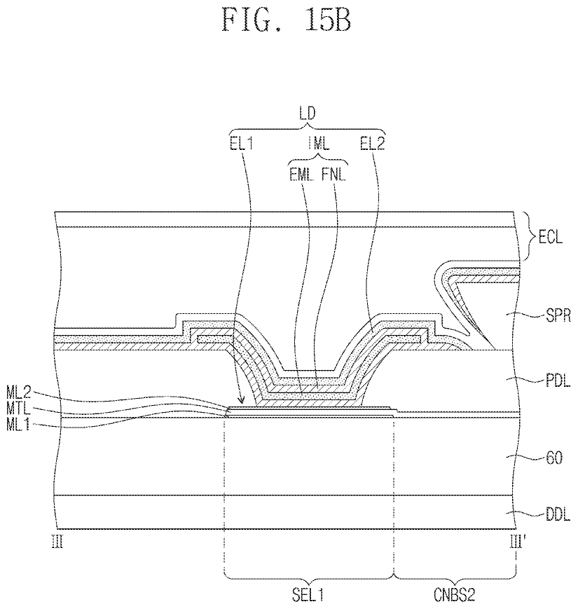

FIG. 14 is a plan schematic view of a display panel according to an embodiment. FIG. 15A is a cross-sectional schematic view taken along line II-II′ of FIG. 14. FIG. 15B is a schematic cross-sectional view taken along line III-III′ of FIG. 14.

Referring to FIG. 14, a first electrode ELla may include first sub electrodes SEL1 and a connection pattern layer CNPb electrically connecting the first sub electrodes SEL1 to each other. The connection pattern layer CNPb may include a first sub connection part CNBS1 and a second sub connection part CNBS2. For example, the connection pattern layer CNPb may include first connection parts CNB1 electrically connecting adjacent first sub electrodes SEL1 in the first direction DR1 and second connection parts CNB2b electrically connecting adjacent first sub-electrodes SEL1 in the second direction DR2, and the second connection parts CNB2b may include a first sub connection part CNBS1 disposed in the non-folding areas NFA3 and NFA4 and a second sub connection part CNBS2 disposed in the folding area FA2.

Referring to FIG. 15A, the first sub electrode SEL1 and the first sub connection part CNBS1 may have a multilayer structure. The first sub electrode SEL1 and the first sub connection part CNBS1 may include metal layers. For example, the first sub electrode SEL1 and the first sub connection part CNBS1 may have a three-layer structure. According to an embodiment, the first sub electrode SEL1 and the first sub connection part CNBS1 may include a first conductive layer ML1, a metal layer MTL disposed in the first conductive layer ML1, and a second conductive layer ML2 disposed on the metal layer MTL. Each of the first conductive layer ML1 and the second conductive layer ML2 may include a transparent conductive layer. For example, the connection electrode 700 may be disposed on at least one side surface of the body 100, on which the external electrode 400 is not provided. The transparent conductive layer may include transparent conductive oxide such as indium tin oxide (ITO), indium zinc oxide (IZO), zinc oxide (ZnO), or indium zinc tin oxide (IZTO). In another example, the transparent conductive layer may include a conductive polymer such as poly(3,4-ethylenedioxythiophene) (PEDOT), a metal nanowire, graphene, and the like. The metal layer MTL may include a metal. For example, the metal layer MTL may include molybdenum, silver, titanium, copper, aluminum, or an alloy thereof.

The first sub connection part CNBS1 and the first sub electrode SEL1 may have the same configuration as each other. The first sub connection part CNBS1 may be formed by the same process as the first sub electrode SEL1. For example, the first sub connection part CNBS1 may be formed in a process of patterning an opening defined in the first electrode EL1 (see FIG. 14), e.g., the first electrode EL1. The first sub connection part CNBS1 may have the same configuration as the first sub electrode SEL1, but embodiments are not limited thereto.

Referring to FIG. 15B, the first sub electrode SEL1 may have a multilayer structure. The first sub electrode SEL1 may include a first conductive layer ML1, a metal layer MTL disposed on the first conductive layer ML1, and a second conductive layer ML2 disposed on the metal layer MTL. The second sub connection part CNBS2 may have a single-layer structure. According to an embodiment, the second sub connection part CNBS2 may include a metal layer MTL. The metal layer MTL formed in the first sub electrode SEL1 and the metal layer MTL formed in the second sub connection part CNBS2 may have the same configuration. For example, the metal layer MTL formed in the first sub electrode SEL1 and the metal layer MTL formed in the second sub connection part CNBS2 may be formed by the same process. For example, the metal layer MTL formed in the second sub connection part CNBS2 may be formed by depositing only the metal layer MTL without depositing the first conductive layer ML1 and the second conductive layer ML2 on an area overlapping the second sub connection part CNBS2 by using a separate mask or may be formed by patterning the first conductive layer ML1 and the second conductive layer ML2 on the area overlapping the second sub connection part CNBS2.

Referring to FIGS. 14, 15A and 15B, the display panel DPa according to an embodiment may include the second sub connections CNBS2 in the folding area FA2. During the folding operation, stress may occur in a connection pattern layer CNPa provided in a first electrode ELla, and stress may be concentrated in the connection pattern layer CNPa disposed in the folding area FA2. The first sub connection part CNBS1 may have a third-layer structure and may include a first conductive layer ML1, a metal layer MTL, and a second conductive layer ML2. Each of the first conductive layer ML1 and the second conductive layer ML2 may include transparent conductive oxide having strong rigidity, and cracks may be generated in the first conductive layer ML1 and the second conductive layer ML2 during the folding operation. Therefore, in the folding area FA2, the connection pattern layer CNPa may be omitted from the first conductive layer ML1 and the second conductive layer ML2, and the second sub connection parts MTL formed by only the highly flexible metal layer MTL may be formed to disperse the compression and tensile stress acting on the second sub connection parts CNBS2 during the folding operation, thereby preventing the cracks from occurring. For example, as a whole formed between the connection pattern layer CNPa between the first sub electrodes SEL1, a voltage drop phenomenon of the first sub electrode SEL1 disposed in the folding area FA2 may be prevented from occurring.

For example, the number of second sub connection parts CNBS2 aligned in the first direction DR1 may gradually increase as being closer to the folding axis FX (see FIG. 14). As the number of second sub connection parts CNBS2 gradually increases as being closer to the folding axis FX (see FIG. 14), the compression and tensile stress that acts on the connection pattern layer CNPa overlapping with the folding area FA2 may be efficiently dispersed to prevent the second connection pattern layers CNP2a from being damaged due to the folding.

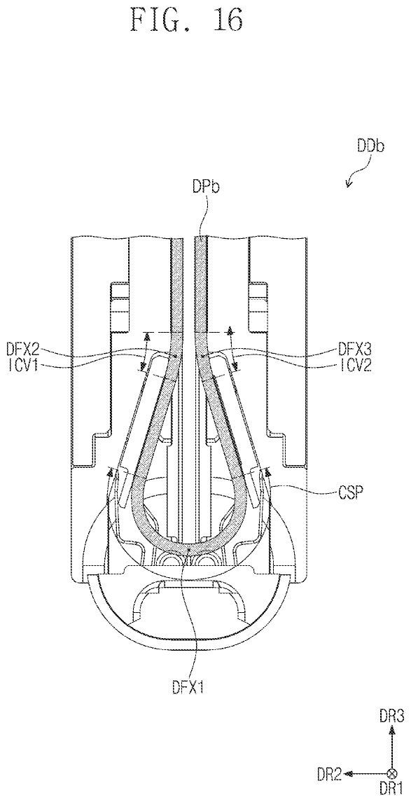

FIG. 16 is a schematic cross-sectional view of a display device according to an embodiment.

Referring to FIG. 16, the display panel DPb provided in the display device DDb may be bent to have a certain curvature during the folding operation. For example, the display panel DPb may be folded in the same shape as dumbbells during the folding operation. The display panel DPb may include a first dumbbell folding axis DFX1, a second dumbbell folding axis DFX2, and a third dumbbell folding axis DFX3. A curvature folded by the first dumbbell folding axis DFX1 and a curvature folded by the second dumbbell folding axis DFX2 and the third dumbbell folding axis DFX3 may be different from each other. For example, the curvature folded by the first dumbbell folding axis DFX1 may be greater than the curvature folded by the second dumbbell folding axis DFX2 and the third dumbbell folding axis DFX3. A portion bent by the first dumbbell folding axis DFX1 may be defined as a curved part CSP, and portions bent by the second dumbbell folding axis DFX2 and the third dumbbell folding axis DFX3 may be defined as a first reverse curvature part ICV1 and a second reverse curvature part ICV2. The first reverse curvature part ICV1 and the second reverse curvature part ICV2 may be bent against the curved part CSP.

Referring to FIG. 12, a density of the connection pattern layer CNP overlapping the curved part CSP may be different from a density of the connection pattern layer CNP overlapping the first reverse curvature part ICV1 and the second reverse curvature part ICV2. For example, the density of the connection pattern layer CNP overlapping the curved part CSP having a large curvature may be less than that of the connection pattern layer CNP overlapping the first reverse curvature part ICV1 and the second reverse curvature part ICV2, each of which has a small curvature.

According to the embodiment, the density of the connection pattern layer in the folding area and the density of the connection pattern layer in the non-folding area may be different from each other. For example, the density of the connection pattern layer in the folding area may be less than the density of the connection pattern layers in the non-folding area, and thus, in case that the compression and tensile stresses acting on the connection pattern layer during the folding operation may be dispersed to prevent the damage due to the folding of the connection pattern layer from occurring.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a base layer bendable with respect to a virtual axis;
a driving element layer comprising a transistor; and
a light emitting element layer comprising:
a first electrode,
a plurality of emission layers disposed on the first electrode, and
a plurality of second electrodes disposed on the emission layers, wherein:
at least one of the plurality of second electrodes is electrically connected to the transistor,
the first electrode comprises:
a plurality of first sub electrodes overlapping the plurality of emission layers, and
a connection pattern layer that electrically connects the first sub electrodes to each other,
the connection pattern layer comprises:
a first connection pattern layer that electrically connects the plurality of first sub electrodes to each other in a first direction parallel to the virtual axis; and
a second connection pattern layer that electrically connects the plurality of first sub electrodes to each other in a second direction intersecting the first direction, and
a density of the first connection pattern layer is greater than a density of the second connection pattern layer.

2. The display panel of claim 1, wherein a folding area that is folded with respect to the virtual axis and a non-folding area that is not folded with respect to the virtual axis are defined in the display panel.

3. The display panel of claim 2, wherein a density of the second connection pattern layer overlapping the folding area is less than a density of the second connection pattern layer overlapping the non-folding area.

4. The display panel of claim 3, wherein the density of the second connection pattern layer overlapping the folding area gradually decreases as being closer to the virtual axis.

5. The display panel of claim 2, wherein:
the first connection pattern layer comprises a plurality of first connection parts that electrically connect the plurality of first sub electrodes, which are adjacent to each other in the first direction, to each other, and
the second connection pattern layer comprises a plurality of second connection parts that electrically connect the plurality of first sub electrodes, which are adjacent to each other in the second direction, to each other.

6. The display panel of claim 5, wherein a first distance between two second connection parts, which are adjacent to each other in the folding area, of the second connection parts in the first direction are different from a second distance between two second connection parts, which are adjacent to each other in the non-folding area, of the second connection parts in the first direction.

7. The display panel of claim 6, wherein the first distance in the folding area is greater than the second distance in the non-folding area.

8. The display panel of claim 5, wherein a number of the plurality of second connection parts in the folding area in a same surface size and a number of the plurality of second connection parts in the non-folding area in the same surface size are different from each other.

9. The display panel of claim 8, wherein the number of the plurality of second connection parts disposed in the first direction gradually decreases as being closer to the virtual axis.

10. The display panel of claim 5, wherein the plurality of second connection parts comprise:
a plurality of first sub connection parts having a multilayer structure; and
a plurality of second sub connection parts having a single-layer structure.

11. The display panel of claim 10, wherein:
each of the plurality of first sub connection parts comprises:
a first conductive layer;
a metal layer disposed on the first conductive layer; and
a second conductive layer disposed on the metal layer, and
each of the plurality of second sub connection parts comprises the metal layer.

12. The display panel of claim 10, wherein:
the plurality of first sub connection parts are disposed in the non-folding area, and
the plurality of second sub connection parts are disposed in the folding area.

13. The display panel of claim 12, wherein a number of the plurality of second sub connection parts disposed in the first direction gradually increases as being closer to the virtual axis.

14. The display panel of claim 2, further comprising:
a voltage line that receives a power voltage; and
a plurality of connection lines that connect the voltage line to the first electrode,
wherein the voltage line and the plurality of connection lines are disposed outside the first electrode.

15. The display panel of claim 14, wherein a density of the plurality of connection lines disposed in the folding area is greater than a density of the plurality of connection lines disposed in the non-folding area.

16. The display panel of claim 1, wherein the light emitting element layer further comprises:
a pixel defining layer including a pixel opening, through which a portion of the first electrode is exposed, the pixel defining layer disposed on the first electrode; and
a separator disposed on the pixel defining layer,
wherein each of the plurality of emission layers overlaps the pixel opening.

17. The display panel of claim 16, wherein the connection pattern layer overlaps the separator in a plan view.

18. The display panel of claim 1, further comprising:
a connection line that electrically connects the transistor to the at least one of the plurality of second electrodes, the connection line comprises:
a first connection portion connected to the at least one of the plurality of second electrodes;
a second connection portion connected to the transistor; and
an extension part extending from the first connection portion and electrically connecting the first connection portion to the second connection portion.

19. The display panel of claim 18, wherein the connection pattern layer does not overlap the first connection portion in a plan view.

20. A display panel including a folding area that is folded with respect to a virtual axis and a non-folding area that is not folded with respect to the virtual axis, the display panel comprising:
a driving element layer comprising a transistor; and
a light emitting element layer comprising:
a first electrode,
a plurality of emission layers disposed on the first electrode, and
a plurality of second electrodes disposed on the emission layers, wherein:
at least one of the plurality of second electrodes is electrically connected to the transistor,
the first electrode comprises:
a plurality of first sub electrodes overlapping the plurality of emission layers, and
a connection pattern layer that electrically connects the plurality of first sub electrodes to each other, and
a density of the connection pattern layer in the folding area and a density of the connection pattern layer in the non-folding area are different from each other.

21. The display panel of claim 20, wherein the density of the connection pattern layer in the folding area gradually decreases as being closer to the virtual axis.

22. The display panel of claim 20, wherein
the connection pattern layer comprises:
a plurality of first connection parts that electrically connect the first sub electrodes, which are adjacent to each other in a first direction parallel to the virtual axis, to each other; and
a plurality of second connection parts that electrically connect the first sub electrodes, which are adjacent to each other in a second direction intersecting the first direction, to each other.

23. The display panel of claim 22, wherein a first distance between two second connection parts, which are adjacent to each other in the folding area, of the second connection parts in the first direction are different from a second distance between two second connection parts, which are adjacent to each other in the non-folding area, of the second connection parts in the first direction.

24. The display panel of claim 23, wherein the first distance in the folding area is greater than the second distance in the non-folding area.

25. The display panel of claim 22, wherein a number of the plurality of second connection parts in the folding area and a number of the plurality of second connection parts in the non-folding area are different from each other.

26. The display panel of claim 25, wherein the number of the plurality of second connection parts disposed in the first direction gradually decreases as being closer to the virtual axis.

27. A display panel including a folding area that is folded and a non-folding area that is not folded with respect to a virtual axis, the display panel comprising:
a driving element layer comprising a transistor; and
a light emitting element layer comprising:
a first electrode,
a plurality of emission layers disposed on the first electrode, and
a plurality of second electrodes disposed on the emission layers, wherein:
each of the plurality of second electrodes is electrically connected to the transistor, the first electrode comprises:
a plurality of first sub electrodes overlapping the plurality of emission layers, and
a connection pattern layer that electrically connects the first sub electrodes to each other,
the connection pattern layer comprises:
a plurality of first sub connection parts having a multilayer structure; and
a plurality of second sub connection parts having a single-layer structure,
the plurality of first sub connection parts are disposed in the non-folding area, and
the plurality of second sub connection parts are disposed in the folding area.

28. The display panel of claim 27, wherein:
each of the plurality of first sub connection parts comprises:
a first conductive layer;
a metal layer disposed on the first conductive layer; and
a second conductive layer disposed on the metal layer, and
each of the plurality of second sub connection parts comprises the metal layer.

29. The display panel of claim 27, wherein a number of the plurality of second sub connection parts disposed in a direction parallel to the virtual axis gradually increases as being closer to the virtual axis.
